(19) United States
(12) Patent Application Publication
(10) Pub. No.: US 2026/0190596 A1
(43) Pub. Date: Jul. 2, 2026

(54) HIGH EFFICIENCY MULTILAYER TRANSPARENT PHOTOVOLTAICS BASED ON A LAYER-BY-LAYER DEPOSITION

(71) Applicant: Board of Trustees of Michigan State University, East Lansing, MI (US)

(72) Inventors: Richard Royal LUNT, Williamston, MI (US); Matthew BATES, Hillsboro, OR (US)

(73) Assignee: Board of Trustees of Michigan State University, East Lansing, MI (US)

(21) Appl. No.: 18/868,066

(22) PCT Filed: Jul. 17, 2023
(86) PCT No.: PCT/US2023/027933

§ 371 Date: Nov. 22, 2024

Related U.S. Application Data
(60) Provisional application No. 63/389,874, filed on Jul. 16, 2022.

(51) Int. Cl. H10K 30/30; H10K 30/50; H10K 30/82; H10K 85/10; H10K 101/40; H10K 102/10

(52) U.S. Cl. CPC H10K 30/353; H10K 30/50; H10K 30/82; H10K 85/113; H10K 2101/40; H10K 2102/103

(57) ABSTRACT

A transparent photovoltaic device includes a substrate, a first electrode on the substrate, a second electrode, and a plurality of planar photoactive layers between the first electrode and the second electrode. The device has a largest absorption peak of less than 430 nm or greater than 650 nm.

### CROSS-REFERENCE TO RELATED APPLICATIONS

This application claims the benefit of U.S. Provisional Patent Application 63/389,874, filed Jul. 16, 2022. This application is related to U.S. patent application Ser. No. ______, Attorney Docket No. 6550-000443-US and PCT Patent Application No. ______, Attorney Docket No. 6550-000445-WO-POA, both filed simultaneously on Jul. 17, 2023. The entire disclosures of each of the above applications are incorporated herein by reference.

### FIELD

The present disclosure relates to high efficiency multilayer transparent photovoltaics based on a layer-by-layer deposition.

### BACKGROUND

This section provides background information related to the present disclosure which is not necessarily prior art.

Transparent photovoltaics (TPVs) are a rapidly emerging field of research and industrial production that possess the power to meet the energy demand via integration with existing infrastructure and new avenues of deployment. TPVs are an important complement to traditional photovoltaics (PVs) as they can be deployed on windows, greenhouses, cars, cellphones, and any other surface that is unavailable for integration with opaque PVs. Unlike traditional solar technologies which often require new infrastructure or a repurposing of space to make solar energy fields, TPVs can be installed seamlessly into existing surfaces to reduce or minimize costs and environmental impact. TPVs are commonly classified as either non-wavelength selective (spatially dispersed or thin opaque PVs) or wavelength selective. This distinction is important as these types of TPVs have different theoretical limits as a function of average visible transmittances (AVT). Wavelength selective TPVs offer a route to the highest possible combination of power conversion efficiency (PCE) and average visible transmittance (AVT) by selectively harvesting ultra-violet (UV) and near-infrared (NIR) light. This is captured in the light utilization efficiency (LUE=PCE×AVT), which is a good metric for tracking progress in the field.

Traditional TPVs have achieved high PCEs but are typically limited to AVTs less than 70%, and more often less than 50% due to parasitic absorption of supporting layers and visible absorption of most donor materials. To date, the best wavelength selective TPV has achieved an LUE of 4.16% using a bulk-heterojunction (BHJ) blended active layer consisting of an NIR absorbing polymer and non-fullerene acceptor (NFA). Most demonstrations of high efficiency (PCE>5%) wavelength selective TPVs have utilized a BHJ structure. Although BHJ architectures often result in the best OPV performance, scaleup of such structures can be challenging. An important parameter in BHJ architectures is the ratio of donor polymer to acceptor NFA, with a suitable ratio typically at 1:1.5 setting a minimum amount of polymer required and thus limiting the AVT.

### SUMMARY

This section provides a general summary of the disclosure, and is not a comprehensive disclosure of its full scope or all of its features.

TPVs offer an opportunity to integrate existing infrastructure with renewable energy. OPVs are important facilitators for wavelength selective TPVs because of their strong selective absorption in the NIR that enables simultaneously high PCE and AVT. The recent rise of OPVs and TPVs has been driven in large part by the development of non-fullerene acceptors (NFAs) as highly adaptable deep NIR harvesting materials. In the example herein, sequential LBL deposition of a selectively NIR absorbing non-traditional acceptor polymer is paired with a NIR absorbing donor IEICO-4F that is typically considered a non-fullerene acceptor via solvent orthogonality. With full optimization of the active layers and top electrode, the example herein demonstrates transparent photovoltaics with a PCE of 8.8%, AVT of 40.9%, and a LUE of 3.6%. The LBL approach enables unambiguous optical modeling of the device structure to extract exciton diffusion lengths of 120 nm and 140 nm for the polymer and IEICO-4F, respectively. Furthermore, the example herein demonstrates impact of acceptor thickness on power generation and optical performance.

The example herein demonstrates implementation of NIR wavelength selective high efficiency LBL TPVs. The example utilizes a solution processed LBL approach to formulate a planar heterojunction (HJ) of an NIR absorbing polymer and NFA and demonstrate an suitable TPV with this approach. Often in BHJs the role of various materials as a donor or acceptor can be hidden, whereas these roles are clearly defined in LBL structures. Notably, the example utilizes the polymer as an electron accepting material and the NFA as an electron donor with an inverted structure. Polymer thickness is varied from 5 to 85 nm and its impact on the optical and electrical performance is thoroughly evaluated. After thorough optimization, a LBL TPV with PCE of 8.8%, AVT of 40.9%, and an LUE of 3.6%, comparable to the best TPVs reported to date, is demonstrated. Transfer matrix optical modeling is enabled by the LBL approach and used to extract exciton diffusion lengths for PTB7-Th and IEICO-4F of at least 120 nm and 140 nm, respectively. The example demonstrates the potential of LBL wavelength selective TPVs as an important and alternative approach to BHJs for future devices.

At least one example embodiment relates to a transparent photovoltaic device.

In at least one example embodiment, the transparent photovoltaic device includes a substrate, a first electrode on the substrate, a second electrode, and a plurality of planar photoactive layers between the first electrode and the second electrode. The device has a largest absorption peak of less than 430 nm or greater than 650 nm.

In at least one example embodiment, at least one of the plurality of planar photoactive layers has an exciton diffusion length of greater than 50 nm.

In at least one example embodiment, all of the plurality of planar photoactive layers have an exciton diffusion length of greater than 50 nm.

In at least one example embodiment, at least one of the plurality of planar photoactive layers has a charge collection length of greater than 50 nm.

In at least one example embodiment, in all of the plurality of planar photoactive layers have a charge collection length of greater than 50 nm.

In at least one example embodiment, the plurality of planar photoactive layers includes a donor layer and an acceptor layer. The donor layer includes a first photoactive material. The acceptor layer includes a second photoactive material.

In at least one example embodiment, the first photoactive material includes a polymer, a non-fullerene acceptor, a small molecule, or any combination thereof. The second photoactive material includes a polymer or a small molecule.

In at least one example embodiment, the first photoactive material includes the polymer.

In at least one example embodiment, wherein the polymer is selected from the group consisting of PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof.

In at least one example embodiment, the first photoactive material includes the non-fullerene acceptor.

In at least one example embodiment, the non-fullerene acceptor is selected from the group consisting of ITIC, Y6 (BTP-4F), ITIC-4F, ITIC-2F, ITIC-4CI, ITIC-M, ITIC-M, ITIC-Th, IDIC-4F, N3, BTP-4F-12 (Y6-BO), DTY6, IEICO-4F, IEICO-4CI, BTP-eC9, eC9-2CI, Y7, BTP-4CI-12, TPT-10, TPT10-C8C12, IDT-2Br, COTIC-4F, COTIC-4CI, IHIC, 6TIC, FBR, o-IDTBR, IO-4CI, L8-BO, L8-BO-F, ZY-4CI, COi8DFIC (06T-4F), BODIPY, or any combination thereof.

In at least one example embodiment, the first photoactive material includes the small molecule.

In at least one example embodiment, the second photoactive material includes the polymer.

In at least one example embodiment, the polymer is selected from the group consisting of PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof.

In at least one example embodiment, the second photoactive material includes the small molecule.

In at least one example embodiment, the donor layer and the acceptor layer are in direct contact. The donor layer is substantially free of the second photoactive material. The acceptor layer is substantially free of the first photoactive material.

In at least one example embodiment, the transparent photovoltaic device further includes a planar-mixed region between a first planar active layer. The planar-mixed region includes the first photoactive material and the second photoactive material. The planar-mixed region defines a thickness of less than 10 nm.

In at least one example embodiment, one of the first photoactive material and the second photoactive material has a quantum yield of greater than or equal to 15% and the other of the first photoactive material and the second photoactive material has a quantum yield of greater than or equal to 2%.

In at least one example embodiment, the first photoactive material has a first quantum yield. The second photoactive material has a second quantum yield. A sum of the first quantum yield and the second quantum yield is greater than or equal to 20%.

In at least one example embodiment, the donor layer defines a thickness ranging from 5 nm to 200 nm. The acceptor layer defines a thickness ranging from 5 nm to 200 nm.

In at least one example embodiment, the first photoactive material has a peak absorption of greater than or equal to 650 nm. The second photoactive material has a peak absorption of greater than or equal to 650 nm.

In at least one example embodiment, the peak absorption of the first photoactive material is greater than or equal to 850 nm.

In at least one example embodiment, the entire device has an average visible transmittance (AVT) of greater than or equal to 30%.

In at least one example embodiment, wherein the device has a power conversion efficiency (PCE) of greater than or equal to 6%.

In at least one example embodiment, the device has a light utilization efficiency (LUE) of greater than or equal to 3.

In at least one example embodiment, the device has a LUE of greater than or equal to 3.5.

In at least one example embodiment, the device has CIELAB color space coordinates (a*, b*). a* is less than 0. b* is less than 10.

In at least one example embodiment, a* is less than 0. b* is less than 0

In at least one example embodiment, the device has CIELAB color space coordinates (a*, b*). A magnitude of a* is less than 15. A magnitude of b* is less than 15.

In at least one example embodiment, the device has a color rendering index (CRI) of greater than or equal to 70.

In at least one example embodiment, the device has a maximum external quantum efficiency (EQE) of greater than or equal to 50% at a wavelength of greater than 650 nm.

In at least one example embodiment, the plurality of planar photoactive layers includes greater than two planar photoactive layers.

In at least one example embodiment, each of the plurality of planar photoactive layers has a tortuosity of less than 0.2.

In at least one example embodiment, each of the plurality of planar photoactive layers has a porosity of less than 0.2. In at least one example embodiment, the device has an open circuit voltage within 80% of the excitonic limit.

In at least one example embodiment, each of the plurality of planar photoactive layers has a root mean square (RMS) roughness of less than or equal to 10 nm.

At least one example embodiment relates to a method of preparing a multi-layer transparent photovoltaic (PV) device.

In at least one example embodiment, the method includes forming a first photoactive layer precursor by depositing a first solution including a first solvent and a first electroactive material onto a substrate. The method further includes, after the forming the first photoactive layer precursor, forming a second photoactive layer precursor by depositing a second solution including a second solvent and a second electroactive material onto the first photoactive layer precursor. The method further includes forming the multi-layer PV device by drying the first photoactive layer precursor and the second photoactive layer precursor. The multi-layer PV device has a largest absorption peak of less than 430 nm or greater than 650 nm.

In at least one example embodiment, during the forming the second photoactive layer, less than 25% by volume of the first photoactive material is removed by the second solvent.

In at least one example embodiment, the forming the first photoactive layer and the forming the second active layer each include spin-coating, spray coating, slot-die coating, web coating, curtain coating, vacuum deposition, or any combination thereof.

In at least one example embodiment, the forming the multi-layer PV device includes annealing.

In at least one example embodiment, the substrate is an electrode.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a schematic illustration of a photovoltaic (PV) in accordance with at least one example embodiment. FIG. 1B is a schematic view of a layered photoactive material in accordance with at least one example embodiment. FIG. 1C is a schematic view of a layered photoactive material having a mixed region in accordance with at least one example embodiment.

FIG. 2 is a flowchart illustrating a method of making a multi-layered PV device in accordance with at least one example embodiment.

FIGS. 3A-3C relate to active materials and architecture used for photovoltaic devices. FIG. 3A shows chemical structures of PTB7-Th, polymer acceptor, and IEICO-4F, a non-fullerene acceptor functioning as an electron donor. FIG. 3B is a graph illustrating transmission data through neat films of PTB7-Th (light green), IEICO-4F (dark green), and a sequentially deposited bilayer of PTB7-Th and IEICO-4F (blue) on zinc oxide and indium tin oxide covered glass substrates. FIG. 3C is a schematic showing inverted bilayer semitransparent device architecture and the sequentially spin-coated bilayer nature of the active layers.

FIGS. 4A-4B are J-V and EQE curves for annealing temperature optimization. FIG. 4A is a graph illustrating current-voltage characteristic curves for devices annealed at different temperatures. FIG. 4B is a graph illustrating corresponding EQE curves. Devices annealed for 10 minutes unless specified otherwise. IEICO-4F was dissolved in 73.5% o-xylene, 24.5% n-butanol, and 2% 1-chloronaphthalene. The device architecture was 120 nm ITO, 20 nm ZnO, 40 nm PTB7-Th, 55 nm IEICO-4F, 7 nm MoO3, 80 nm Ag.

FIG. 5 is a table showing J-V parameters for annealing temperature optimization.

FIGS. 6A-6C relate to solvent additive optimization. FIG. 6A is a graph illustrating characteristic current-voltage (J-V) curves and for opaque devices (OPVs) with different 1-chloronaphthalene doping in the IEICO-4F solution. FIG. 6B is a graph illustrating external quantum efficiencies (EQE) for opaque devices (OPVs) with different 1-chloronaphthalene doping in the IEICO-4F solution. FIG. 6C is a graph illustrating transmission data for the device stack up to the active layers for the opaque devices (ITO, ZnO, PTB7-Th, and IEICO-4F).

FIG. 7 is a table showing solvent additive optimization device parameters. J-V parameters were collected from a minimum of five devices under each condition.

FIGS. 8A-8B relate to dark current for 1-chloronaphthalene and polymer thickness optimized devices. FIG. 8A is a graph illustrating dark current for devices made with 0% and 4% 1-chloronaphthalene. FIG. 8B is a graph illustrating dark current for devices with different PTB7-Th thickness.

FIG. 9 is a table showing dark J-V fit parameters for 1-chloronaphthalene and polymer thickness optimized devices.

FIGS. 10A-10F relate to polymer thickness optimization. FIG. 10A is a graph illustrating characteristic current-voltage (J-V) curves for transparent devices with different PTB7-Th thickness. FIG. 10B is a graph illustrating external quantum efficiencies (EQE) for transparent devices with different PTB7-Th thickness. FIG. 10C is a graph illustrating transmission for transparent devices with different PTB7-Th thickness. FIG. 10D is a graph illustrating transmission data for polymer films of varying thickness on glass substrates covered with ITO and ZnO. FIG. 10E is a graph illustrating dependence of V_{OC} on light intensity (L) with linear fits of V_{OC} vs ln(L) and the slope proportional to k_{B}Tq−¹. FIG. 10F is a graph illustrating fitted dark J-V data for 5, 40, and 60 nm PTB7-Th.

FIG. 11 is a table showing polymer thickness optimization device parameters. J-V parameters were collected from a minimum of five devices under each condition. PCE and LUE were calculated with the integrated JSC in parentheses.

FIGS. 12A-12B relate to light intensity dependent voltage and photocurrent for polymer thickness devices. FIG. 12A is a graph illustrating dependence of V_{OC} on light intensity (L) with linear fits of V_{OC} vs ln(L) and the slope proportional to k_{B}Tq-1. FIG. 12B is a graph illustrating dependence of J_{SC} on L with power fits of J_{SC} a Ls plotted on log-log scale.

FIG. 13 is a table showing PTB7-Th, Ag, and Alq3 thickness dependent device optical parameters. J-V parameters were collected from a minimum of five devices under each condition.

FIGS. 14A-14C relate to Ag thickness dependence on device performance. FIG. 14A is a graph illustrating characteristic current-voltage (J-V) curves for transparent devices with different Ag thickness. FIG. 14B is a graph illustrating external quantum efficiencies (EQE) for transparent devices with different Ag thickness.

FIG. 14C is a graph illustrating transmission for transparent devices with different Ag thickness. Transmission curves with 10, 12, and 16 nm Ag were measured with an index matched antireflection coating on the glass side.

FIG. 15 is a table showing Ag thickness dependent device parameters. J-V parameters were collected from a minimum of five devices under each condition. PCE and LUE calculated with the integrated JSC in parentheses. AVT for 10, 12, and 16 nm Ag measured with an antireflection coating on the glass side of the substrate.

FIGS. 16A-16C relate to Alq₃ thickness dependence on device performance. FIG. 16A is a graph illustrating characteristic current-voltage (J-V) curves for transparent devices with different Alq₃ thickness. FIG. 16B is a graph illustrating external quantum efficiencies (EQE) for transparent devices with different Alq₃ thickness. FIG. 16C is a graph illustrating transmission for transparent devices with different Alq₃ thickness. Transmission curves were measured with an index matched antireflection coating on the glass side.

FIG. 17 is a table showing Alq₃ thickness dependent device parameters. J-V parameters were collected from a minimum of five devices under each condition. PCE and LUE calculated with the integrated JSC in parentheses.

FIGS. 18A-18C relate to optimized transparent photovoltaic device data. FIG. 18A is a graph illustrating characteristic current-voltage (J-V) curves for fully optimized transparent photovoltaic (TPV) devices (blue) compared with the optimized opaque device (OPV, black). FIG. 18B is a graph illustrating external quantum efficiencies (EQE) with integrated short circuit current (dashed lines) for fully optimized transparent photovoltaic (TPV) devices (blue) compared with the optimized opaque device (OPV, black). TPVs were fabricated with 7 nm MoO₃, 12 nm Ag, and 40 nm Alq₃ on top of the sequentially deposited active layers. FIG. 18C is a graph illustrating transmission data for the complete TPV device stacks with an antireflection coating attached on the glass substrate side with index matching gel (blue), and for the device stack up to the active layers for the opaque devices (black).

FIGS. 19A-19D relate to eesthetic characterization of TPVs and literature comparison. FIG. 19A is a photograph of a transparent photovoltaic (TPV) device with 35 nm PTB7-Th and 12 nm Ag. FIG. 19B is a graph illustrating photon balance for the optimized TPV. A comparison of literature single-junction, ultraviolet or near-infrared wavelength selective TPV performances with devices prepared in this work for FIG. 19C PCE vs AVT, and FIG. 19D LUE vs AVT with the Shockley-Queisser limits for segmented and transparent single-junction PVs shown as dashed lines.

FIG. 20 is a graph illustrating calculated transmission through different top electrodes. Transparency through three different top electrodes on a glass substrate calculated with transfer matrix optical modeling.

FIGS. 21A-21F are graphs relating to photon balances for Ag thickness dependent TPVs. External quantum efficiency (EQE), transmission (T), reflection (R), and the photon balance (EQE+T+R) data for devices with different Ag thickness.

FIGS. 22A-22F are graphs relating to photon balances for PTB7-Th thickness dependent TPVs. External quantum efficiency (EQE), transmission (T), reflection (R), and the photon balance (EQE+T+R) data for devices with different PTB7-Th thickness.

FIGS. 23A-23E are graphs relating to photon balances for Alq₃ thickness dependent TPVs. External quantum efficiency (EQE), transmission (T), reflection (R), and the photon balance (EQE+T+R) data for devices with different Alq₃ thickness and an antireflection coating on the glass side of the device.

FIGS. 24A-24C are graphs relating to impact of antireflection coating on optical performance. Transmission and reflection data for devices with and without an antireflection coating (ARC) on the glass side for transparent photovoltaics with (a) 10 nm, (b) 12 nm, and (c) 16 nm Ag electrode layers.

FIG. 25 is a graph illustrating shelf life of bilayer photovoltaic devices. (a) Current-voltage curves and (b) normalized device parameters for large area (A=27 mm²) transparent devices encapsulated with getter pads and stored in the dark in an oxygen and moisture free atmosphere between tests.

FIG. 26 is a graph illustrating example EQE fit using transfer matrix optical modeling. Transfer matrix optical modeling is paired with a nonlinear regression analysis to fit the calculated EQE to the experimentally measured EQE. Exciton diffusion lengths are extracted from the fit for PTB7-Th and IEICO-4F.

FIG. 27 is a table optimized transparent photovoltaic device parameters. J-V parameters were collected from a minimum of five devices under each condition. PCE and LUE calculated using the integrated JSC in parentheses.

FIG. 28 is a table showing the impact of antireflection coating on optical performance. PCE and LUE were calculated from integrated JSC in parentheses.

FIGS. 29A-29D relate to solvent orthogonality for PTB7-Th in accordance with at least some example embodiments. FIG. 29A illustrates transmission data for 23 nm PTB7-Th films. FIG. 29B illustrates transmission data for 48 nm PTB7-Th films. FIG. 29C illustrates normalized thickness of PTB7-Th films. FIG. 29D illustrates transmission data for a PTB7-Th.

FIGS. 30A-30C relate to spectrally resolved photoluminescent quenching for polymer films in accordance with at least some example embodiments. FIG. 30A illustrates excitation scans of 90 nm PTB7-Th films emitting at 810 nm. FIG. 30B illustrates extinction coefficient of PTB7-Th as a function of wavelength. FIG. 30C illustrates the ratio of photons emitted by PTB7-Th.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

A photoactive layer is a layer including (or consisting of or consisting essentially of) a photoactive material. A photoactive material is a material that absorbs light to generate charge carriers (known as photocurrent). Planar layers are often described as “continuous”, “contiguous”, “neat”, “uniform”, “smooth”, “unmixed”, “pure”, “non-tortuous”, “non-porous”, or “flat,” or “homogeneous.” Tortuosity is a measure of the ratio of lengths of the preferential fluid pathway and a porous media. Porosity is a measure of percentage of void space in a material or layer. Root mean square roughness is a measure of the overall surface roughness of a layer.

High efficiency organic photovoltaics (OPVs) can be prepared by sequentially depositing donor materials and acceptor materials in a layer-by-layer (LBL) method. Such devices have achieved PCEs comparable to the best BHJ OPVs, but have seen limited use in TPVs. The LBL approach offers better control over the precise thickness of each active material without inherently compromising the morphology and device performance. Additionally, there have been few studies on the impact of polymer thickness in LBL devices on TPV performance and aesthetics. One study involved fabrication of opaque photovoltaics with a visibly absorbing donor polymer D18. Devices with 65 nm D18 yielded PCE=12.6% and AVT=22.8% for a 2.9% LUE. Another study demonstrated TPVs with 8.0% PCE and 23.0% AVT with LUE=1.8%. The polymer (PTB7-Th) was used as a donor and the thickness was varied independently of other parameters from 50 to 80 nm, although the best TPV utilized 45 nm. Notably, LBL TPVs have not yet demonstrated AVT above 25%.

The present disclosure provides multilayer PV devices prepared by LBL deposition. In at least one example embodiment, the PV devices are high efficiency PV or TPV devices. The PV devices may include a plurality of planar photoactive layers including an acceptor layer and a donor layer. The acceptor layer may include a selectively NIR absorbing polymer or small molecule. The donor layer may include a polymer, non-fullerene acceptor, or small molecule such as IEICO-4F. As will be described in greater detail below, the device may include greater than two active layers.

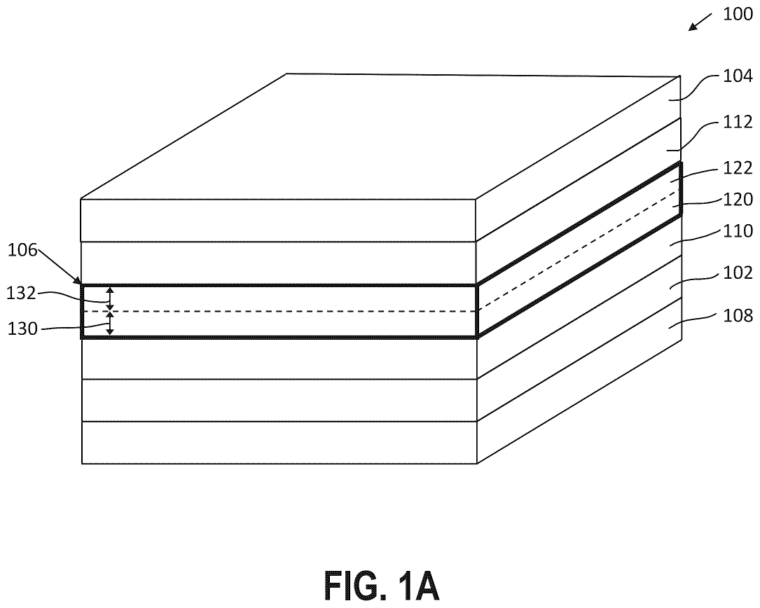

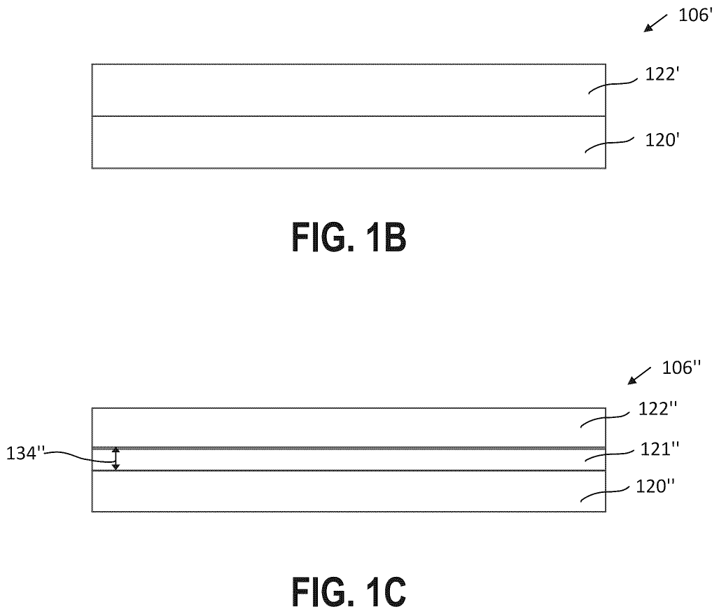

FIG. 1A illustrates a photovoltaic (PV) device 100 in accordance with at least one example embodiment. The PV 100 generally includes a first electrode 102, a second electrode 104, and a layered photoactive material 106 between the first and second electrodes 102, 104. In at least one example embodiment, one or both of the first and second electrodes 102, 104 may be on a substrate 108. In at least one example embodiment, the first electrode 102 may be positioned on the substrate 108 and include materials that act as the electrode, such that the substrate and electrode are visibly indistinguishable (not shown).

In at least one example embodiment, the electrodes 102, 104 may include thin metal (e.g., Ag, Au, Al, and/or Cu), indium tin oxide (ITO), tin oxide, aluminum doped zinc oxide, metallic nanotubes, metal nanowires (e.g., Ag, Au, Al, and/or Cu), conductive low-α stack, low-e single-silver stack, low-e double-silver stack, low-e triple-silver stack, or any combination thereof. In at least one example embodiments, one or both of the electrodes 102, 104 are transparent.

The substrate 108 may be transparent or opaque. In at least one example embodiment, the substrate 108 includes glass, plastic (e.g., polythethylene, polycarbonate, polymethyl methacrylate, and/or polydimethylsiloxane), or any combination thereof.

In at least one example embodiment, the PV device 100 further includes or more adjunct layers, such as a first adjunct layer 110 and a second adjunct layer 112. In the example embodiment shown, the first adjunct layer 110 is between the first electrode 102 and the layered photoactive material 106. The second adjunct layer 112 is between the second electrode 104 and the layered photoactive material 106. Each of the adjunct layers 110, 112 may include a hole transport layer, an electron blocking layer, a buffer layer, an electron transport layer, a hole blocking layer, an electron extraction layer, or any combination thereof. Although the example embodiment of FIG. 1 shows two adjunct layers 110, 112, a PV in accordance with the present disclosure may be free of adjunct layers, include a single adjunct layer, or include more than two adjunct layers. In at least one example embodiment, the first adjunct layer is a hole transport layer and the second adjunct layer is an electron transport layer. In at least one other example embodiment, the first adjunct layer is an electron transport layer and the second adjunction layer is hole transport layer. In at least one other example embodiment, the first and second adjunct layers may be a conducting or semiconducting wetting layer. In at least one other example embodiment, the first and second adjunct layers may be hole or electron blocking layers. In at least one example embodiment, the adjunct layers may have compositions as described in PCT Patent Application No. PCT/US2019/030209, filed on May 1, 2019, and published as WO2019213265A1, which is incorporated herein by referenced in its entirety.

The layered photoactive material 106 includes a plurality of photoactive layers, such as a first or donor layer 120 and a second or acceptor layer 122. In at least one example embodiment, the plurality of photoactive layers including the donor and acceptor layers 120, 122 are planar photoactive layers. In at least one example embodiment, the plurality of photoactive layers includes greater than or equal to 2 photoactive layers (e.g., greater than or equal to 3 photoactive layers, greater than or equal to 4 photoactive layers, or greater than or equal to 5 photoactive layers). In at least one example embodiment, the plurality of photoactive layers includes less than or equal to 6 photoactive layers (e.g., less than or equal to 5 photoactive layers, less than or equal to 4 photoactive layers, less than or equal to 3 photoactive layers, or less than or equal to 2 photoactive layers).

In at least one example embodiment, the donor layer 120 defines a first thickness 130 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, or greater than or equal to about 175 nm). The first thickness 130 may be less than or equal to about 200 nm (e.g., less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm).

In at least one example embodiment, the donor layer 120 is continuous. As used herein, “continuous” means extending across an entire electrode or other layer and not in an island/sea configuration). In at least one example embodiment, the donor layer 120 is a continuous mesh. In at least one example embodiment, the donor layer 120 is neat. As used herein, “neat” means effectively uniform in composition (as opposed to doped or mixed) and/or that the material is deposited only of itself. In at least one example embodiment, the donor layer 120 consists essentially of a photoactive donor material. In at least one example embodiment, the first thickness 130 is substantially constant or uniform. In at least one example embodiment, the donor layer 120 is substantially uniform in composition. In at least one example embodiment, the donor layer 120 is smooth. As used herein, “smooth” means having a roughness of less than about one tenth.

In at least one example embodiment, the acceptor layer 122 defines a second thickness 132 of greater than or equal to about 5 nm (e.g., greater than or equal to about 10 nm, greater than or equal to about 15 nm, greater than or equal to about 20 nm, greater than or equal to about 25 nm, greater than or equal to about 30 nm, greater than or equal to about 40 nm, greater than or equal to about 50 nm, greater than or equal to about 75 nm, greater than or equal to about 100 nm, greater than or equal to about 125 nm, greater than or equal to about 150 nm, or greater than or equal to about 175 nm). The second thickness 132 may be less than or equal to about 200 nm (e.g., less than or equal to about 175 nm, less than or equal to about 150 nm, less than or equal to about 125 nm, less than or equal to about 100 nm, less than or equal to about 75 nm, less than or equal to about 50 nm, less than or equal to about 40 nm, less than or equal to about 30 nm, less than or equal to about 25 nm, less than or equal to about 20 nm, less than or equal to about 15 nm, or less than or equal to about 10 nm).

In at least one example embodiment, the acceptor layer 122 is continuous. In at least one example embodiment, the acceptor layer 122 is a continuous mesh. In at least one example embodiment, the acceptor layer 122 is neat. In at least one example embodiment, the acceptor layer 122 consists essentially of a photoactive donor material. In at least one example embodiment, the second thickness 132 is substantially constant or uniform. In at least one example embodiment, the acceptor layer 122 is substantially uniform in composition. In at least one example embodiment, the acceptor layer 122 is smooth.

The first and second thicknesses 130, 132 of the donor and acceptor layers 120, 122 may be the same or different. In at least one example embodiment, when a PV device includes a plurality donor layers 120, the donor layers 120 may have the same or different thicknesses. When a PV device includes a plurality acceptor layers 122, the acceptor layers 122 may have the same or different thicknesses.

FIG. 1B is a schematic view of a layered photoactive material 106′ in accordance with at least one example embodiment. The layered photoactive material 106′ includes a planar donor layer 120′ and a planar acceptor layer 122′. The planar donor and acceptor layers 120′, 122′ may be similar to or the same as the donor and acceptor layers 120, 122 of FIG. 1. In at least one example embodiment, the donor and acceptor layers 120′, 122′ are distinct. For example the donor layer 120′ is substantially free of acceptor material, the acceptor layer 122′ is substantially free of donor material, and the donor and acceptor layers 120′, 122′ are in direct contact with one another. In at least one example embodiment, the layers 120′, 122′ may be in continuous contact with one another. The layered photoactive material 106′ may be free of a planar-mixed region including both donor and acceptor material between the layers 120′, 122′.

FIG. 1C is a schematic view of another layered photoactive material 106″ in accordance with at least one example embodiment. The layered photoactive material 106″ includes a planar donor layer 120″, a planar mixed layer 121″, and a planar acceptor layer 122″. The planar donor and acceptor layers 120″, 122″ may be similar to or the same as the donor and acceptor layered 120, 122 of FIG. 1. The planar mixed layer 121″ may include an admixture and/or blend of donor and acceptor materials. In at least one example embodiment, the planar mixed layer 121″ may define a third or planar mixed thickness 134″ of less than about 10 nm (e.g., less than about 9 nm, less than about 8 nm, less than about 7 nm, less than about 6 nm, less than about 5 nm, less than about 4 nm, less than about 3 nm, less than about 2 nm, or less than about 1 nm).

In at least one example embodiment, each of the plurality of planar of photoactive layers (e.g., the donor and acceptor layers 120, 122) has a root mean square (RMS) roughness of less than or equal to 50 nm (e.g. less than or equal to 40 nm, less than or equal to 30 nm, less than or equal to 20 nm, less than or equal to 10 nm, less than or equal to 5 nm, less than or equal to 4 nm, less than or equal to 3 nm, less than or equal to 2 nm, less than or equal to 1 nm, or or less than or equal to 0.5 nm).

In at least one example embodiment, the donor layer 120 includes a donor including fullerene(s), small organic molecule(s) (as used herein, “small molecule” means<10 nm in any given direction), non-fullerene acceptor(s) (NFA), polymer(s), phthalocynine(s), cyanine(s), coumarin(s), pophyrin(s), naphthalocyanine(s), squaraine(s), perylene(s), thiohphene(s), acene(s), BODIPY(s), rhodamine(s), quinine(s), xanthene(s), naphthalene(s), oxadiazole(s), oxazine(s), acridine(s), arylmethine(s), tetrapyrrole(s), indocarbocyanine(s), oxacarbocyanine(s), thiacarbocyanine(s), merocyanine(s), polymethine(s), organic salt(s), or any combination thereof. In at least one example embodiment, the donor material includes an NFA including ITIC, Y6 (BTP-4F), ITIC-4F, ITIC-2F, ITIC-4CI, ITIC-M, ITIC-M, ITIC-Th, IDIC-4F, N3, BTP-4F-12 (Y6-BO), DTY6, IEICO-4F, IEICO-4CI, BTP-eC9, eC9-2CI, Y7, BTP-4CI-12, TPT-10, TPT10-C8C12, IDT-2Br, COTIC-4F, COTIC-4CI, IHIC, 6TIC, FBR, O-IDTBR, IO-4CI, L8-BO, L8-BO-F, ZY-4CI, COi8DFIC (06T-4F), BODIPY, or a combination thereof). In at least one example embodiment, the donor material includes a polymer including polythiophene(s), polypyrrole(s), polyaniline(s), poly phenylenevinylene(s), poly(carbazole-dithiophene-benzothiadiazole(s), donor-acceptor polymer(s), or any combination thereof. In at least one example embodiment, the polymer includes PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof.

In at least one example embodiment the acceptor layer 122 includes an acceptor including polymer(s), NFA(s), fullerene(s), small organic molecule(s), phthalocynine(s), cyanine(s), coumarin(s), pophyrin(s), naphthalocyanine(s), squaraine(s), perylene(s), thiohphene(s), acene(s), BODIPY(s), rhodamine(s), quinine(s), xanthene(s), naphthalene(s), oxadiazole(s), oxazine(s), acridine(s), arylmethine(s), tetrapyrrole(s), indocarbocyanine(s), oxacarbocyanine(s), thiacarbocyanine(s), merocyanine(s), polymethine(s), organic salt(s), or any combination thereof. In at least one example embodiment, the acceptor is a polymer including polythiophene(s), polypyrrole(s), polyaniline(s), poly phenylenevinylene(s), poly(carbazole-dithiophene-benzothiadiazole(s), donor-acceptor polymer(s), or any combination thereof. In at least one example embodiment, the polymer includes PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof. In at least one example embodiment, the acceptor is a NFA including ITIC, Y6 (BTP-4F), ITIC-2F, ITIC-4F, ITIC-4CI, ITIC-M, ITIC-M, ITIC-Th, IDIC-4F, N3, BTP-4F-12 (Y6-BO), DTY6, IEICO-4F, IEICO-4CI, BTP-eC9, eC9-2CI, Y7, BTP-4CI-12, TPT-10, TPT10-C8C12, IDT-2Br, COTIC-4F, COTIC-4CI, IHIC, 6TIC, FBR, O-IDTBR, IO-4CI, L8-BO, L8-BO-F, ZY-4CI, or any combination thereof.

In at least one example embodiment the acceptor layer 122, the donor layer 120, and/or the layered photoactive material 106 have a tortuosity that is less than 0.2 (e.g., less then or equal to 0.15, less than or equal to 0.1, less than or equal to 0.05, less than or equal to 0.02, less than or equal to 0.01, less than or equal to 0.005, or less than or equal to 0.001).

In at least one example embodiment the acceptor layer 122, the donor layer 120, and/or the layered photoactive material 106 have a porosity that is less than 0.2 (20%) (e.g. less then or equal to 0.15, less than or equal to 0.1, less than or equal to 0.05, less than or equal to 0.02, less than or equal to 0.01, less than or equal to 0.005, or less than or equal to 0.001).

In at least one example embodiment, the donor material in the donor layer 120 has a quantum yield (QY) for luminescence of greater than or equal to about 1% (e.g., greater than or equal to about 2%, greater than or equal to about 3%, greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 15%, greater than or equal to about 20%, greater than or equal to about 25%, greater than or equal to about 30%, greater than or equal to about 40%, greater than or equal to about 50%, greater than or equal to about 60%, greater than or equal to about 70%, or greater than or equal to about 80%). The donor QY may be less than or equal to about 90% (e.g., less than or equal to about 80%, less than or equal to about 70%, less than or equal to about 60%, less than or equal to about 50%, less than or equal to about 40%, less than or equal to about 30%, less than or equal to about 25%, less than or equal to about 20%, less than or equal to about 15%, less than or equal to about 10%, less than or equal to about 9%, less than or equal to about 8%, less than or equal to about 7%, less than or equal to about 6%, less than or equal to about 5%, less than or equal to about 4%, less than or equal to about 3%, or less than or equal to about 2%).

In at least one example embodiment, the acceptor in the acceptor layer 122 has a quantum yield (QY) for luminescence of greater than or equal to about 1% (e.g., greater than or equal to about 2%, greater than or equal to about 3%, greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 15%, greater than or equal to about 20%, greater than or equal to about 25%, greater than or equal to about 30%, greater than or equal to about 40%, greater than or equal to about 50%, greater than or equal to about 60%, greater than or equal to about 70%, or greater than or equal to about 80%). The acceptor QY may be less than or equal to about 90% (e.g., less than or equal to about 80%, less than or equal to about 70%, less than or equal to about 60%, less than or equal to about 50%, less than or equal to about 40%, less than or equal to about 30%, less than or equal to about 25%, less than or equal to about 20%, less than or equal to about 15%, less than or equal to about 10%, less than or equal to about 9%, less than or equal to about 8%, less than or equal to about 7%, less than or equal to about 6%, less than or equal to about 5%, less than or equal to about 4%, less than or equal to about 3%, or less than or equal to about 2%). In at least one example embodiment, the IEICO-4F has a QY of 17.8% in dilute film and a QY of 4.4% in chlorobenzene. The PTB7-Th has a QY in film between 1.6% to 3% and a QY in solution of 19.3%.

In at least one example embodiment, a sum of a donor QY and an acceptor QY for luminescence is greater than or equal to about 10% (e.g., greater than or equal to about 15%, greater than or equal to about 20%, greater than or equal to about 21%, greater than or equal to about 22%, greater than or equal to about 23%, greater than or equal to about 24%, greater than or equal to about 25%, greater than or equal to about 30%, greater than or equal to about 40%, greater than or equal to about 50%, greater than or equal to about 75%, greater than or equal to about 100%, or greater than or equal to about 125%). The sum of the donor QY and the acceptor QY may be less than or equal to about 150% (e.g., less than or equal to about 125%, less than or equal to about 100%, less than or equal to about 75%, less than or equal to about 50%, less than or equal to about 40%, less than or equal to about 30%, less than or equal to about 25%, less than or equal to about 24%, less than or equal to about 23%, less than or equal to about 22%, less than or equal to about 21%, or less than or equal to about 20%).

In at least one example embodiment, the donor layer 120 a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the donor peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the donor layer 120 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 400 nm). In at least one example embodiment, the donor layer 120 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The donor layer 120 may have less than or equal to about six absorption peaks (e.g., less than or equal to about five, less than or equal to about four, less than or equal to about three, or less than or equal to about two) in the above wavelength ranges. In at least one example embodiment, the donor layer 120 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

In at least one example embodiment, the acceptor layer 122 a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the acceptor peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the acceptor layer 122 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 400 nm). In at least one example embodiment, the acceptor layer 122 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The acceptor layer 122 may have less than or equal to about six absorption peaks (e.g., less than or equal to about five, less than or equal to about four, less than or equal to about three, or less than or equal to about two) in the above wavelength ranges. In at least one example embodiment, the acceptor layer 122 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

In at least one example embodiment, the PV device 100 has a peak absorption at a wavelength of greater than or equal to about 650 nm (e.g., greater than or equal to about 660 nm, greater than or equal to about 670 nm, greater than or equal to about 680 nm, greater than or equal to about 690 nm, greater than or equal to about 700 nm, greater than or equal to about 720 nm, greater than or equal to about 740 nm, greater than or equal to about 760 nm, greater than or equal to about 780 nm, greater than or equal to about 800 nm, greater than or equal to about 820 nm, greater than or equal to about 840 nm, greater than or equal to about 860 nm, greater than or equal to about 880 nm, or greater than or equal to about 900 nm). In at least one example embodiment, the device peak absorption is at a wavelength of less than or equal to about 1,200 nm (e.g., less than or equal to about 1,150 nm, less than or equal to about 1,100 nm, less than or equal to about 1,050 nm, less than or equal to about 1,000 nm, or less than or equal to about 950 nm). In at least one example embodiment, the PV device 100 has a peak absorption at a wavelength of less than or equal to about 450 nm (e.g., less than or equal to about 440 nm, less than or equal to about 430 nm, less than or equal to about 420 nm, less than or equal to about 410 nm, or less than or equal to about 400 nm). In at least one example embodiment, the PV device 100 has greater than or equal to one absorption peak (e.g., greater than or equal to two absorption peaks, greater than or equal to three absorption peaks, greater than or equal to four absorption peaks, greater than or equal to five absorption peaks) in the above wavelength ranges. The PV device 100 may have less than or equal to about six absorption peaks (e.g., less than or equal to about five, less than or equal to about four, less than or equal to about three, or less than or equal to about two) in the above wavelength ranges. In at least one example embodiment, the entire PV device 100 has no highest absorption peak (e.g., no first and second highest absorption peaks; no first, second, or third highest absorption peaks) in a range of greater than or equal to about 450 nm to less than or equal to about 650 nm (e.g., greater than or equal to about 440 nm to less than or equal to about 660 nm, greater than or equal to about 430 nm to less than or equal to about 670 nm, greater than or equal to about 420 nm to less than or equal to about 680 nm, greater than or equal to about 410 nm to less than or equal to about 690 nm, greater than or equal to about 400 nm to less than or equal to about 700 nm).

As used herein, “exciton diffusion length” means the average distance over which an exciton will diffuse before it is annihilated to form heat or light. It is similar to, or synonymous with, the root mean square displacement of the exciton over the natural lifetime of the exciton. In at least one example embodiment, each of the plurality of photoactive layers (e.g., the donor layer 120, the acceptor layer 22) and/or the multilayered photoactive material 106 has a exciton diffusion length of greater than or equal to about 10 nm (e.g., greater than or equal to about 20 nm, greater than or equal to about 30 nm, greater than or equal to about 40 nm, greater than or equal to about 50 nm, greater than or equal to about 100 nm, greater than or equal to about 150 nm, greater than or equal to about 200 nm, greater than or equal to about 250 nm, greater than or equal to about 300 nm, or greater than or equal to about 350 nm). The exciton diffusion length may be less than or equal to about 400 nm (e.g., less than or equal to about 350 nm, less than or equal to about 300 nm, less than or equal to about 250 nm, less than or equal to about 200 nm, less than or equal to about 100 nm, less than or equal to about 50 nm, less than or equal to about 40 nm, less than or equal to about 30 nm, less than or equal to about 20 nm, or less than or equal to about 10 nm).

As used herein, “charge collection length” means the length over which the charge can be readily collected before it is trapped or annihilated. In at least one example embodiment, each of the plurality of photoactive layers (e.g., the donor layer 120, the acceptor layer 22) and/or the multilayered photoactive material 106 has a charge collection length of greater than or equal to about 10 nm (e.g., greater than or equal to about 20 nm, greater than or equal to about 30 nm, greater than or equal to about 40 nm, greater than or equal to about 50 nm, greater than or equal to about 100 nm, greater than or equal to about 200 nm, greater than or equal to about 300 nm, or greater than or equal to about 400 nm). The charge collection length may be less than or equal to about 500 nm (e.g., less than or equal to about 400 nm, less than or equal to about 300 nm, less than or equal to about 200 nm, less than or equal to about 100 nm, less than or equal to about 50 nm, less than or equal to about 40 nm, less than or equal to about 30 nm, or less than or equal to about 20 nm).

In at least one example embodiment, the PV device 100 may have a power conversion efficiency (PCE) of greater than or equal to about 6% (e.g., greater than or equal to about 7%, greater than or equal to about 8%, greater than or equal to about 9%, greater than or equal to about 10%, or greater than or equal to about 15%). The PCE may be less than or equal to about 20% (e.g., less than or equal to about 15%, less than or equal to about 10%, less than or equal to about 9%, less than or equal to about 8%, or less than or equal to about 7%).

In at least one example embodiment, the entire PV device 100 has an average visible transmittance (AVT) of greater than or equal to about 0% (e.g., greater than or equal to about 10%, greater than or equal to about 20%, greater than or equal to about 30%, greater than or equal to about 40%, greater than or equal to about 50%, greater than or equal to about 60%, greater than or equal to about 70%, greater than or equal to about 80%, or greater than or equal to about 90%). The AVT may be less than or equal to about 100% (e.g., less than or equal to about 90%, less than or equal to about 80%, less than or equal to about 70%, less than or equal to about 60%, less than or equal to about 50%, less than or equal to about 40%, less than or equal to about 30%, or less than or equal to about 20%).

In at least one example embodiment, the PV device 100 has an light utilization efficiency (LUE) of greater than or equal to about 3.0 (e.g., greater than or equal to about 3.1, greater than or equal to about 3.2, greater than or equal to about 3.3, greater than or equal to about 3.4, greater than or equal to about 3.5, greater than or equal to about 3.6, greater than or equal to about 3.8, greater than or equal to about 4.0, greater than or equal to about 3.5, or greater than or equal to about 4.5). The LUE may be less than or equal to about 5.0 (e.g., less than or equal to about 4.5, or less than or equal to about 4.0).

As used herein, “external quantum efficiency” (EQE) is the efficiency of converting photons of a particular wavelength to electrons. In at least one example embodiment, the PV device 100 has a maximum external quantum efficiency (max EQE) of greater than or equal to about 50% (e.g., greater than or equal to about 60%, greater than or equal to about 70%, greater than or equal to about 75%, greater than or equal to about 80%, greater than or equal to about 85%, or greater than or equal to about 90%). The max EQE may be less than or equal to about 95% (e.g., less than or equal to about 90%, less than or equal to about 80%, less than or equal to about 75%, less than or equal to about 70%, or less than or equal to about 60%).

In at least one example embodiment, the PV device 100 has a smallest active layer bandgap of less than or equal to about 1.3 eV.

In at least one example embodiment, the PV device 100 has an open circuit voltage (V_{OC}) of greater than or equal to about 0.60 V (e.g., greater than or equal to about 0.65 V, greater than or equal to about 0.70 V, greater than or equal to about 0.705 V, greater than or equal to about 0.71 V). In at least one example embodiment the V_{OC} voltage is within 80% of the excitonic voltage limit (e.g. within 80%, within 82%, within 84%, within 86%, within 88%, within 90%, within 92%, within 94%, or within 96% of the excitonic voltage limit), as defined in Lunt et al., “Practical Roadmap and Limits to Nanostructured Photovoltaics” (Perspective) Adv. Mat. 23, 5712-5727, 2011, which is incorporated herein by reference.

In at least one example embodiment, the PV device 100 has a fill factor (FF) of greater than or equal to 0.35 (e.g., greater than or equal to 0.40, greater than or equal to 0.45, greater than or equal to 0.50, greater than or equal to 0.55, greater than or equal to 0.60, or greater than or equal to 0.65).

In at least one example embodiment, the PV device 100 has a color rendering index (CRI) of greater than or equal to about 50 (e.g., greater than or equal to about 55, greater than or equal to about 60, greater than or equal to about 65, greater than or equal to about 70, greater than or equal to about 75, greater than or equal to about 80, greater than or equal to about 85, or greater than or equal to about 90). In at least one example embodiment, the PV device 100 has CIELAB color space coordinates (a*, b*). In at least one example embodiment, a magnitude of a* (i.e., |a*|) is less than or equal to about 20 (e.g., less than or equal to about 15, less than or equal to about 10, less than or equal to about 9, less than or equal to about 8, less than or equal to about 7, less than or equal to about 6, or less than or equal to about 5). In at least one example embodiment, a magnitude of b* (i.e., |b*|) is less than or equal to about 20 (e.g., less than or equal to about 15, less than or equal to about 10, less than or equal to about 9, less than or equal to about 8, less than or equal to about 7, less than or equal to about 6, or less than or equal to about 5). In at least one example embodiment, a magnitude of a* (i.e., |a*|) and a magnitude of b* (i.e., |b*|) are each less than or equal to about 20 (e.g., less than or equal to about 15, less than or equal to about 10, less than or equal to about 9, less than or equal to about 8, less than or equal to about 7, less than or equal to about 6, or less than or equal to about 5). In at least one example embodiment the PV device 100 has an a* less than 0 (negative number), and b* is less than 20 (e.g., less than 15, less than 10, or less than 0) so that the color falls within the grey, blue, or green color palette and is not in the yellow, orange, or red color palette.

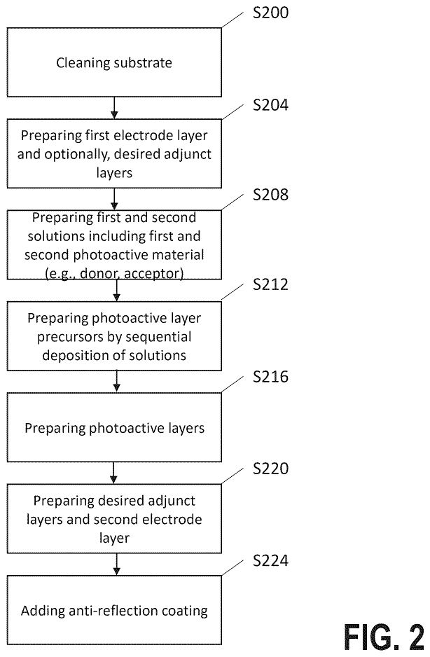

FIG. 2 is a flowchart depicting a method of preparing a PV device in accordance with at least one example embodiment. The method generally includes cleaning a substrate at S200; preparing a first electrode layer and optionally one or more adjunct layers at S204; preparing first and second solutions including first and second photoactive materials at S208; preparing photoactive layer precursors by sequential deposition of solutions at S212; preparing photoactive layers at S216; preparing second electrode layer and optionally desired adjunct layers at S220; and optionally adding desired anti-reflection coating at S224. Each of these steps is described in greater detail below.

The substrate may include materials described above in the discussion of substrate 108. In at least one example embodiment, cleaning a substrate at S200 includes sonication. The sonication may be performed in deionized water, acetone, isopropanol, or any combination thereof. The cleaning may further include drying the substrate after sonication. The drying may include heating the substrate. Cleaning the substrate may further include plasma cleaning, such as under a light vacuum. Cleaning the substrate may further include annealing.

The method includes preparing a first electrode layer and optionally one or more adjunct layers at S204. The layers may have compositions as described above in the discussion of the electrodes 102, 104 and adjunct layers 112, 112. The electrodes and adjunct layers may be prepared by spray coating, slot-die coating, spin coating, curtain coating, web coating, vacuum deposition, or plasma sputtering.

At S208, the method includes preparing first and second materials or solutions including first and second photoactive materials (e.g., donor and active materials). Preparing the first and second solutions may include dissolving the first and second photoactive materials in respective solvents. The solvents may be independently selected from deionized (DI) H₂O, methanol, ethanol, isopropanol, propanol, n-butanol, o-xylene, chloroform, toluene, dichloromethane, benzene, chlorobenzene, di-chlorobenzene, tri-chlorobenzene (1,2,4-trichlorobenzene), hexane, cyclohexane, dimethyl sulfoxide, dimethylformamide, acetone, acetonitrile, tetrahydrofuran, pentane, heptane, diethyl ether, or any combination thereof. Preparing the solvent may further include adding a solvent additive to the first and/or second solution. The solvent additive may include 1-chloronaphthalene, 2-chloronaphthalene, 1,8-diiodooctane, or any combination thereof. The purpose of the solvent additive is increase aggregation and/or ordering in the resulting film. Preparing the solutions may further include heating and/or stirring the solutions.

In at least one example embodiment, the first and second solvents have orthogonality. That is, the first photoactive material is essentially insoluble in the second solvent and the second photoactive material is essentially insoluble in the first solvent. Accordingly, when the second solution is dispensed, the layer including the first solution remains as a neat film and is not substantially redissolved because the first photoactive material is insoluble in the second solvent. Without solvent orthogonality, the first active material layer would be redissolved and either washed away or form a mixed layer with the second photoactive material. In at least one example embodiment, less than about 25% by volume (e.g., less than 20% by weight, less than 15% by weight, or less than 10% by weight) of the first photoactive material is removed by the second solvent.

At S212, the method includes preparing photoactive layer precursors by sequential deposition of the first and second solutions prepared at S208. In at least one example embodiment, the first and second materials are thermally deposited. In at least one example embodiment, first and second materials are alternatively deposited until a desired quantity of layers precursors is formed.

In at least one example embodiment, the first and second solutions are sequentially deposited by spin coating. Each layer may be formed in one or more spin coating steps. Each of the spin coating steps may be performed at a speed of greater than or equal to about 100 RPM (e.g., greater than or equal to about 300 RPM, greater than or equal to about 500 RPM, greater than or equal to about 750 RPM, greater than or equal to about 1,000 RPM, greater than or equal to about 2,000 RPM, greater than or equal to about 3,000 RPM, greater than or equal to about 4,000 RPM, greater than or equal to about 5,000 RPM, greater than or equal to about 6,000 RPM). The speed may be less than or equal to about 7,000 RPM (e.g., less than or equal to about 6,000 RPM, less than or equal to about 5,000 RPM, less than or equal to about 4,000 RPM, less than or equal to about 3,000 RPM, less than or equal to about 2,000 RPM, less than or equal to about 1,000 RPM, less than or equal to about 750 RPM, less than or equal to about 500 RPM, or less than or equal to about 300 RPM). Each of the spin coating steps may be performed for a duration of greater than or equal to about 1 s (e.g., greater than or equal to about 5 s, greater than or equal to about 10 s, greater than or equal to about 20 s, greater than or equal to about 30 s, greater than or equal to about 40 s, greater than or equal to about 50 s, greater than or equal to about 60 s, greater than or equal to about 70 s, or greater than or equal to about 80 s). In at least one example embodiment, the duration may be less than or equal to about 90 s (e.g., less than or equal to about 80 s, less than or equal to about 70 s, less than or equal to about 60 s, less than or equal to about 50 s, less than or equal to about 40 s, less than or equal to about 30 s, less than or equal to about 20 s, less than or equal to about 10 s, or less than or equal to about 5 s). Multiple spin coating steps can be performed at the same or different speeds and durations. In at least one example embodiment, the solutions are sequentially deposited by spray coating, slot-die coating, web coating, curtain coating, vacuum deposition, or any combination thereof.

At S216, the method includes preparing photoactive layers. Preparing the photoactive layers may include annealing the photoactive layers. The annealing may be performed at a temperature of greater than or equal to about 30° C. (e.g., greater than or equal to about 50° C., greater than or equal to about 75° C., greater than or equal to about 100° C., greater than or equal to about 125° C., greater than or equal to about 150° C., or greater than or equal to about 175° C.). The temperature may be less than or equal to about 200° C. (e.g., less than or equal to about 175° C., less than or equal to about 150° C., less than or equal to about 125° C., less than or equal to about 100° C., less than or equal to about 75° C., or less than or equal to about 50° C.). The annealing may be performed for a duration of 30 s (e.g., greater than or equal to about 1 min, greater than or equal to about 2 min, greater than or equal to about 5 min, greater than or equal to about 10 min, or greater than or equal to about 15 min). The duration may be less than or equal to about 20 min. (e.g., less than or equal to about 15 min, less than or equal to about 10 min, less than or equal to about 5 min, less than or equal to about 2 min, or less than or equal to about 1 min).

At S220, the method includes preparing a second electrode layer and optionally one or more adjunct layers. The layers may have compositions as described above in the discussion of the electrodes 102, 104 and adjunct layers 112, 112. The electrodes and adjunct layers may be prepared by spray coating, slot-die coating, spin coating, curtain coating, web coating, vacuum deposition, or plasma sputtering.

At S224, the method may optionally include adding desired anti-reflection coating at S224. In at least one example embodiment, the anti-reflection coating includes TiO₂, SiO₂, ZnO, MgF₂, ZrO₂, CeF₃, or any combination thereof. The anti-reflection coating may be applied to the second electrode by thermal deposition, spray coating, slot-die coating, spin coating, curtain coating, web coating, vacuum deposition, plasma sputtering, or any combination thereof.

In at least one example embodiment, masks may be used in the above steps to define desired area, such as photoactive area.

In at least one example embodiment, the method further includes optimizing PV device performance and AVT by varying one or more of photoactive layer annealing temperature, solvent additive presence and amount, photoactive layer thickness, electrode thicknesses, and/or coating thicknesses.

### Example 1

### Results

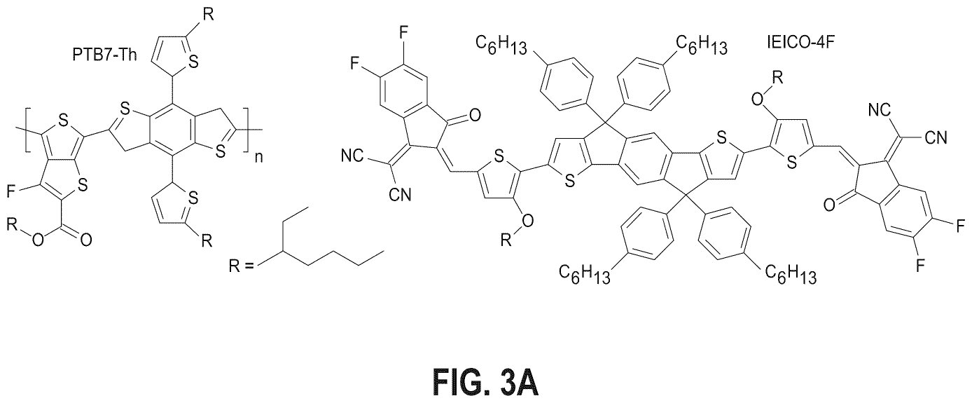

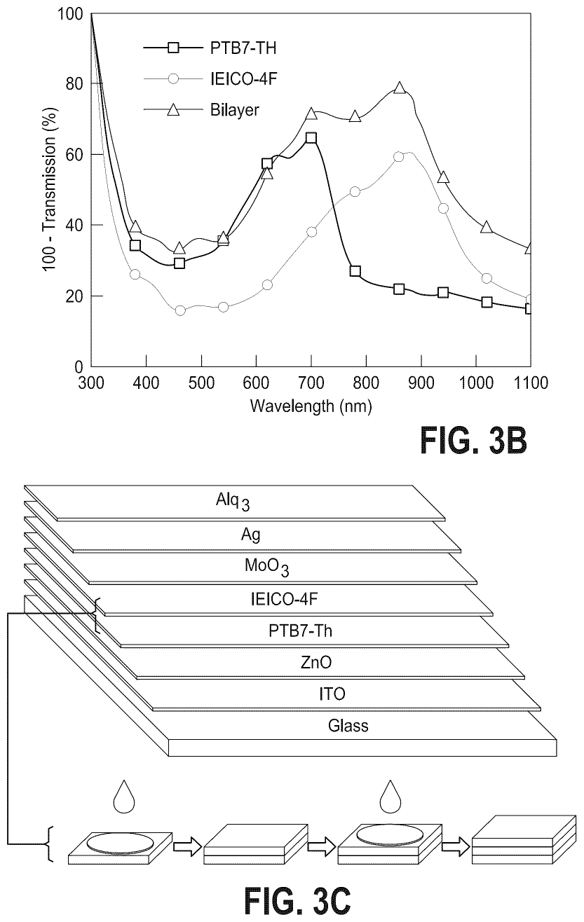

This example involves fabrication of inverted LBL TPVs with the near-infrared absorbing polymer PTB7-Th and NFA IEICO-4F as the electron accepting and donating materials, respectively, where the chemical structures of both are shown in FIG. 3A. PTB7-Th and IEICO-4F provide complementary absorption of NIR light with individual thin film absorption (FIG. 3B) peaks at 700 and ˜900 nm, respectively, while the bilayer exhibits broad NIR absorption from 700 to 900 nm with a desirable transparent window in the visible spectrum. PTB7-Th contributes some visible light absorption with a strong absorptive shoulder at 625 nm.

For the layer order for the inverted architecture (FIG. 3C), the PTV includes a ZnO electron transport layer (20 nm thickness), sequentially deposited active layers, a MoO₃ hole transport layer (7 nm), and a thin Ag top electrode (8-20 nm) with Alq₃ as an antireflection coating (0-50 nm). For reference, opaque devices are fabricated with a thick (80 nm) Ag electrode. The active layers are formed by sequential spin-coating of neat films of PTB7-Th and IEICO-4F utilizing solvent orthogonality. O-xylene readily dissolves IEICO-4F, whereas PTB7-Th is soluble only with stirring and heat. In contrast, the polymer is insoluble in n-butanol which is added at 24% v/v to the IEICO-4F solution to reduce or minimize redissolving of the PTB7-Th neat film during IEICO-4F spin-coating. The solvent additive 1-chloronaphthalene (CN) was added to the IEICO-4F solution at 0-6% v/v. Concentrations of the active layer solutions were used to individually determine the resulting film thicknesses, an important difference in experimental control compared to BHJs which use the donor-to-acceptor ratio to control the resulting morphology.

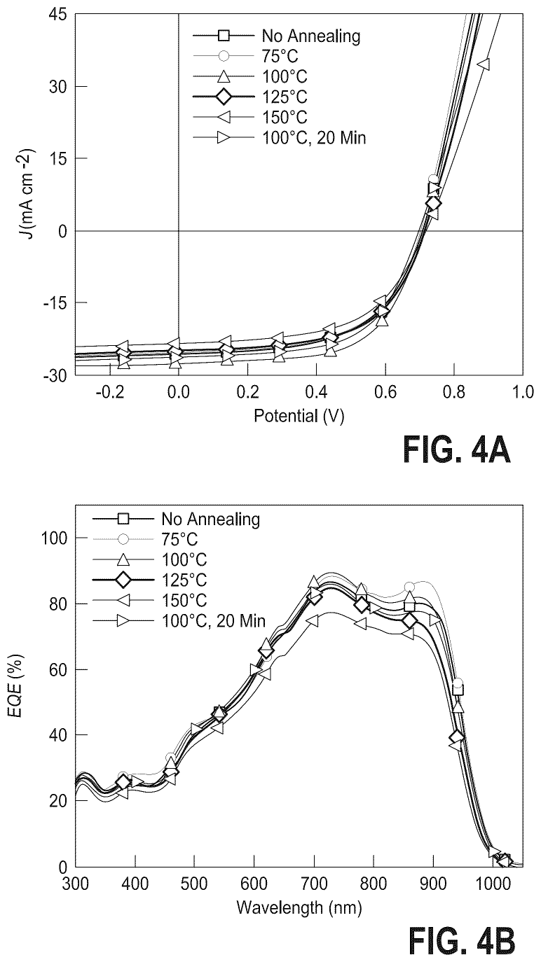

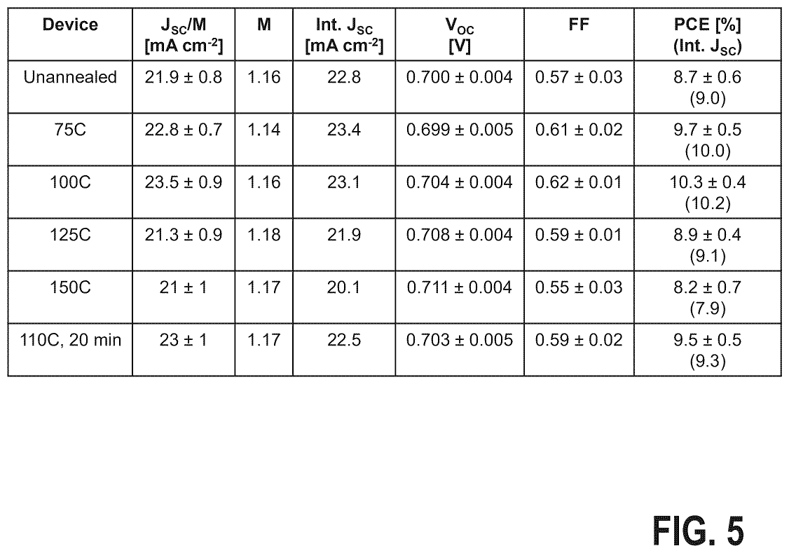

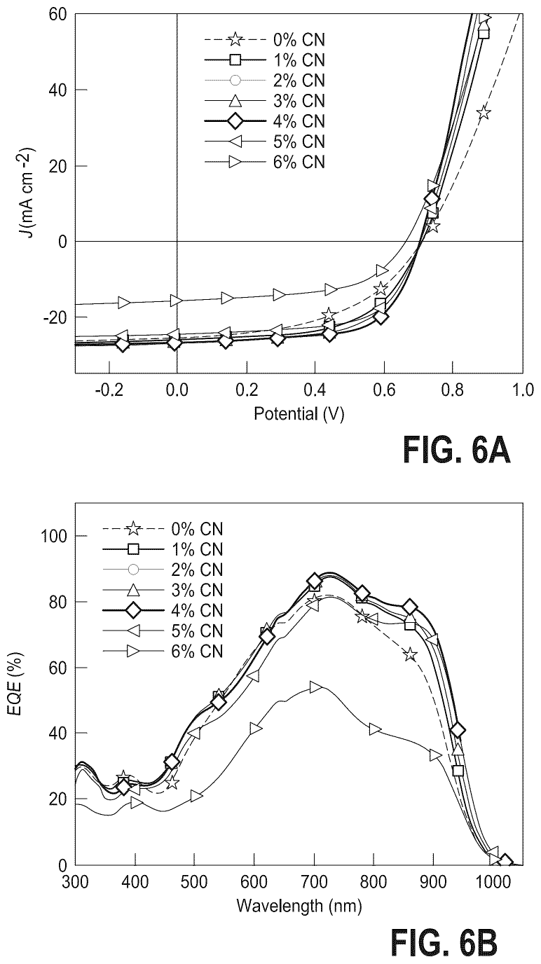

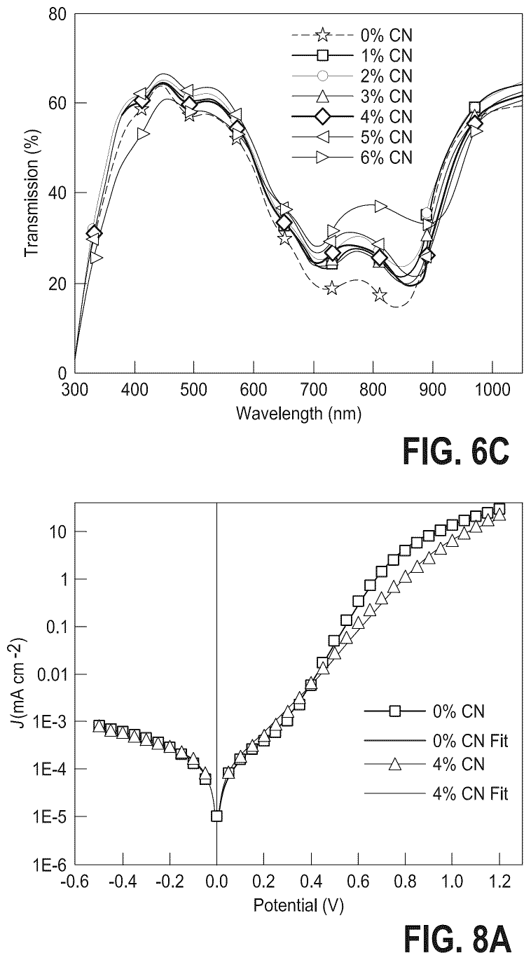

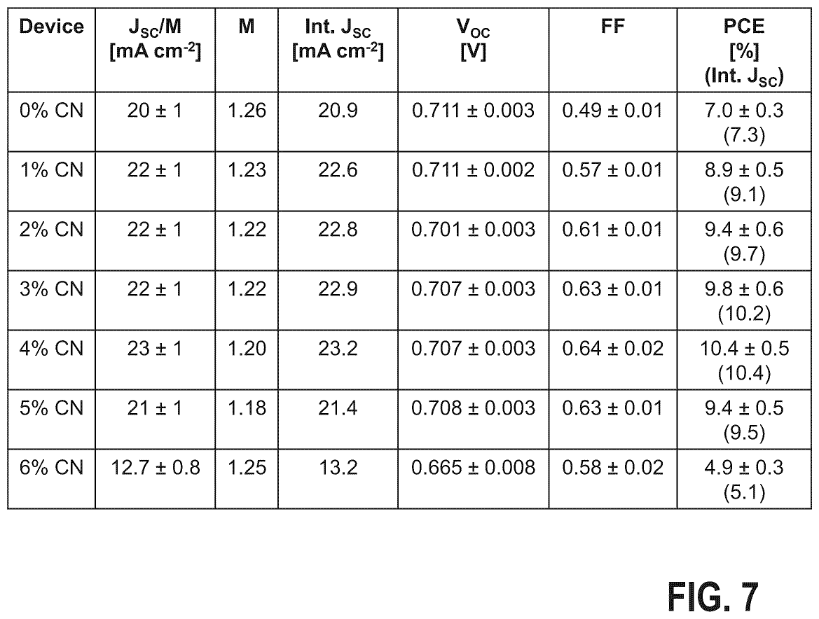

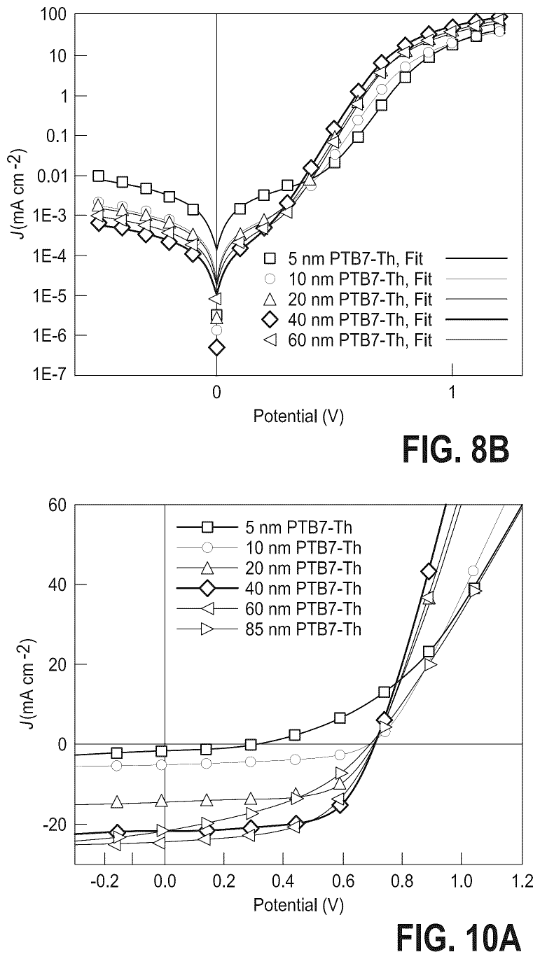

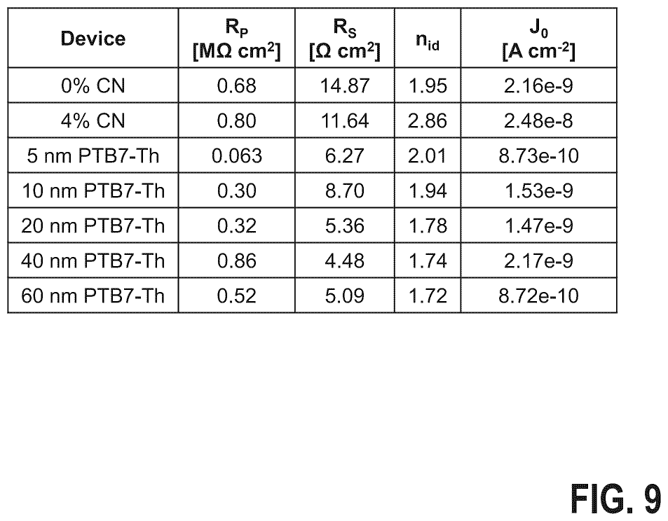

TPV electrical and optical performance is optimized by consideration of important variables affecting the active layers (annealing temperature, solvent additive level, and PTB7-Th thickness) and the top contact (Ag and Alq₃ thickness). Current-voltage (J-V) characteristic curves and external EQE for thermal annealing of the active layers in opaque devices are given in FIGS. 4A-4B with corresponding device parameters, including the spectral mismatch factor (M), in FIG. 5. For opaque devices without thermal annealing, LBL opaque devices achieved a PCE of 8.7%. With annealing at 100° C. for 10 minutes, PCE reached 10.3%. The improvement in device performance comes from equal gains in the short circuit photocurrent (J_{SC}) and fill factor (FF). Solvent additives such as 1,8-diiodoctane and CN have been thoroughly characterized and shown to improve morphology in polymer-NFA LBL PVs by increasing aggregation in the NFA resulting in improved FF and decreased recombination. Interestingly, while solvent additives in pre-mixed BHJ solutions are present with both active layer materials, LBL approaches generally feature solvent additive only in the NFA solution. In the example herein, optimization of CN additive levels in the IEICO-4F solution finds significant improvement in opaque device electronic performance, evidenced in the J-V curves (FIG. 6A) and device parameters (FIG. 7), including J_{SC} corrected with M for each device. Devices without CN have a FF of just 0.49, while optimized devices with 4% CN in the IEICO-4F solution possess a FF of 0.64. CN optimization enhances J_{SC} to a lesser extent with a relative gain of 10% from 0 to 4% CN. The J_{SC} improvement comes almost entirely with the first small addition of CN to IEICO-4F, while FF enhancement is incremental from 0% to 4%, albeit with the largest gain from 0 to 1% CN. The J_{SC} and FF decline rapidly at CN levels greater than 4%, as the photocurrent is reduced by nearly half at 6% CN and the FF to 0.58. The EQE (FIG. 4B) for CN optimization reveals photocurrent improvement across the spectrum upon addition of 4% CN to the IEICO-4F, including in regions of PTB7-Th absorption. Transmission data (FIG. 4C) for glass substrates with ITO, ZnO, PTB7-Th, and IEICO-4F indicate subtle changes in the absorption profile of the active layers. The absorption peak for IEICO-4F is slightly red shifted with the addition of CN suggesting CN influences aggregation or crystallite formation in IEICO-4F. To characterize the PV performance with and without CN doping of the IEICO-4F solution, we report dark J-V spectra for the 0% and 4% devices (FIG. 8A) fitted with the ideal diode equation and the extracted dark J-V parameters in FIG. 9. There is a clear difference in the shape of the dark J-V curve under positive bias conditions and this is seen in the increase of the ideality factor (n_{id}) and the series resistance (R_{S}). Both devices possess n_{id}>1.5, indicating relatively high levels of trap-assisted recombination. Considering the shape of the J-V curves and the FF improvement from 0% to 4% CN, it is clear that the combination of increased shunt resistance (R_{P}) and decreased R_{S} caused by the presence of CN during neat film formation is an important factor for device improvement. The increased ratio of R_{P} to R_{S} could also improve η_{CC} of holes through the IEICO-4F, causing improved EQE across the spectrum and a higher FF.

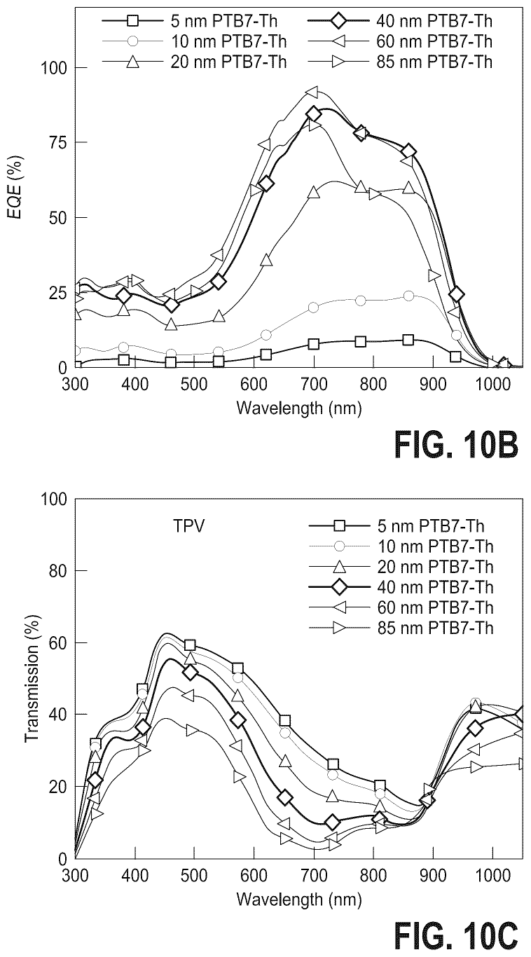

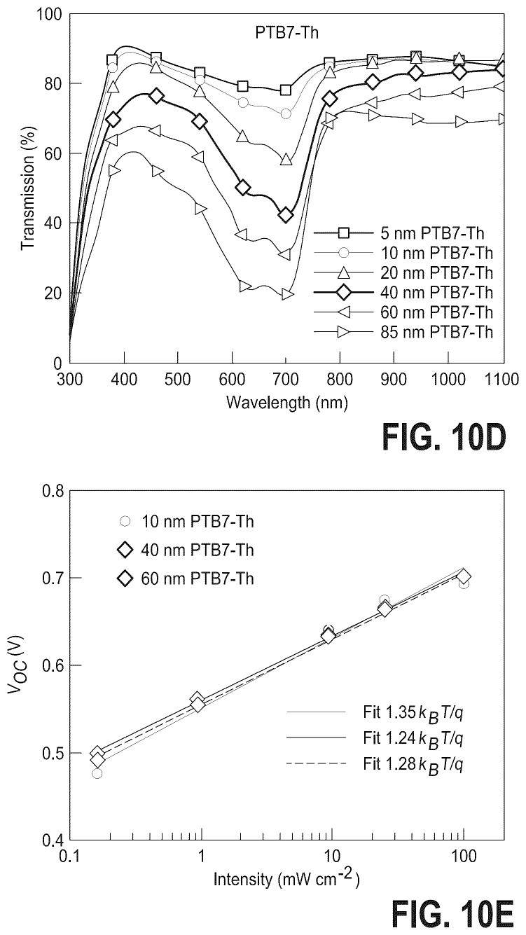

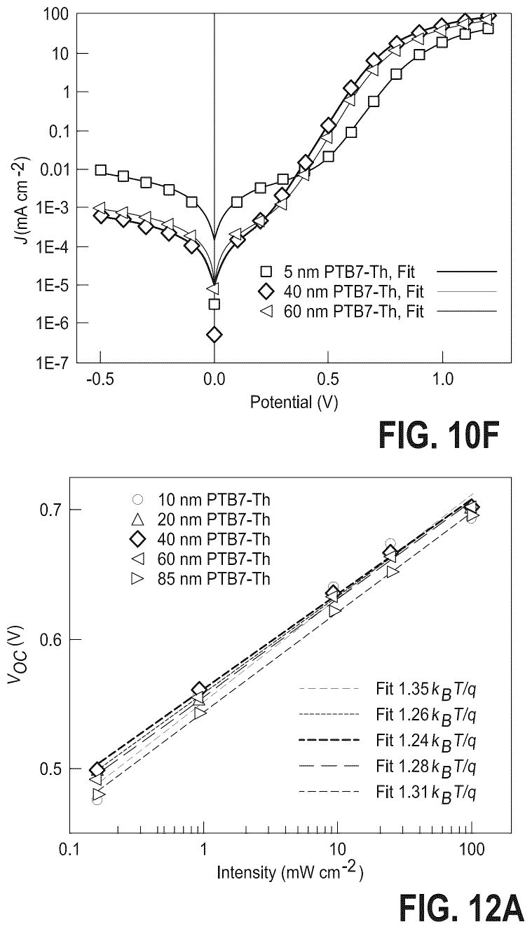

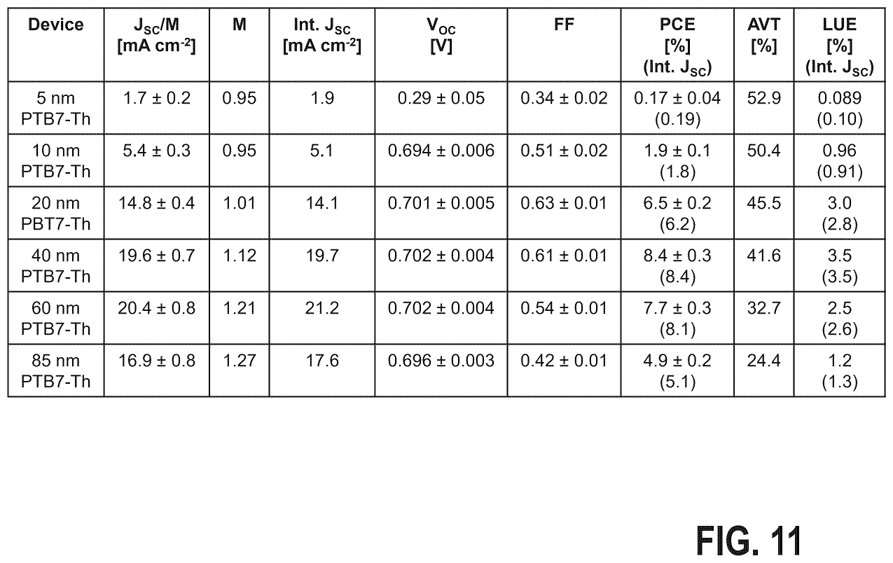

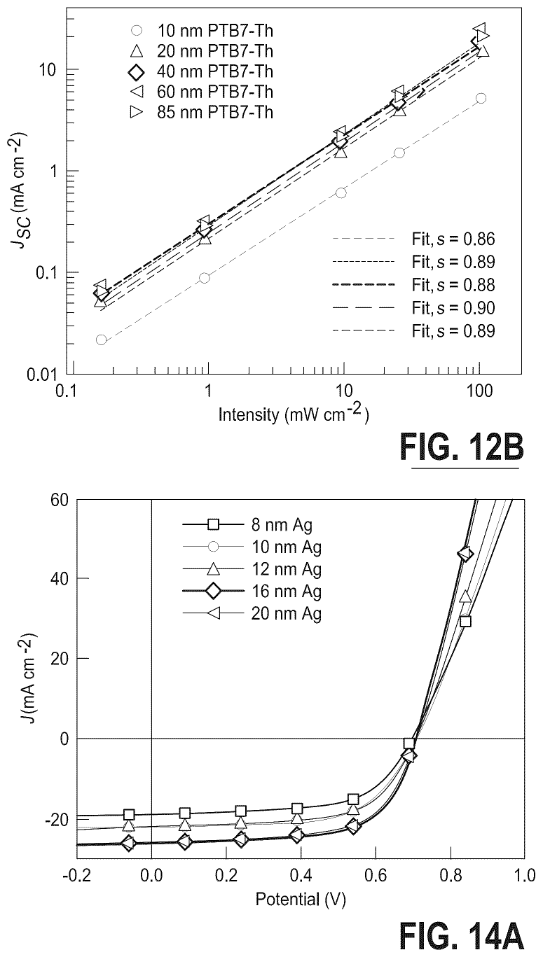

An important difference in device fabrication between BHJ and bilayer devices is the freedom to vary the individual thicknesses of the two active materials independently, enabling the ability to readily extract characteristic lengths through transfer matrix optical modeling. Here, the full range of polymer thickness from 5 nm to 85 nm in TPVs while fixing the IEICO-4F thickness. PTB7-Th thickness dependent J-V curves (FIG. 10A) demonstrate interesting trends in J_{SC}, open circuit voltage (V_{OC}), and FF (FIG. 11). The V_{OC} is stable down to 10 nm of PTB7-Th before decreasing sharply at 5 nm. As expected, the J_{SC} decreases from 20 mA cm⁻² for 40 nm PTB7-Th to less than 2 mA cm⁻² for 5 nm PTB7-Th. Very thick polymer layers (85 nm) lead to reduced photocurrent, while the ideal range for PCE of 40 to 60 nm demonstrates stable J_{SC}. The FF reaches an optimum in TPVs with 20 nm PTB7-Th and declines quickly for polymer thicknesses less than 20 nm and greater than 40 nm. The EQE spectra shows a maximum integrated J_{SC} for 60 nm PTB7-Th, with 40 nm demonstrating a slightly diminished EQE at the PTB7-Th peak and into the visible portion of the spectrum. Decreasing polymer thickness below 40 nm reveals an unexpected trend where the EQE is reduced across the entire spectrum, including the deeper NIR region of pure IEICO-4F absorption. Light intensity (P₀) dependence of the V_{OC} (FIGS. 8E and 10A) shows a meaningful increase in slope when the polymer thickness deviates from 40 nm. J_{SC} (FIG. 12B) meanwhile does not show any strong dependance on P₀ as a function of PTB7-Th thickness.

Fitted dark J-V data as a function of polymer thickness (FIGS. 8F, 6B, 7) reveals several trends. The reverse dark saturation current (J₀) is largely independent of polymer thickness, while n_{id}, R_{S}, and the shunt (parallel) resistance R_{P} all show a strong dependence on PTB7-Th thickness. R_{S} and R_{P} reach a minimum and maximum, respectively, at the suitable thickness of 40 nm in strong agreement with the combination of high J_{SC} and FF observed in the J-V curves.

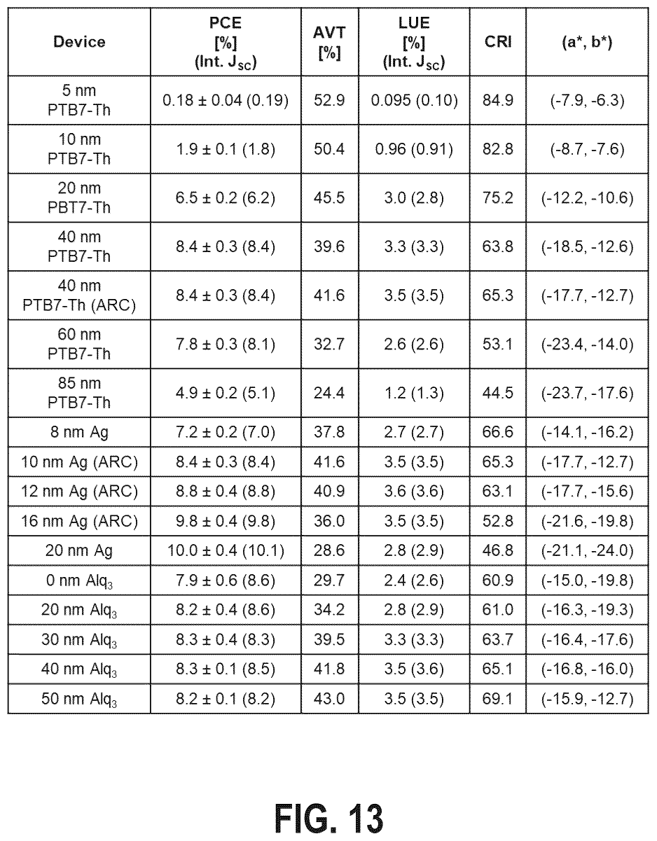

In addition to the impact on electrical performance, polymer thickness is an important variable to optimize for its impact on the optical qualities of the TPVs. PTB7-Th accounts for most of the visible absorption in the device, and this is made clear from transmission measurements for the entire TPV device stack (FIG. 10C) and for the device stack up to the PTB7-Th layer (FIG. 10D). As expected, important optical figures of merit including the AVT, color rendering index (CRI), and the CIELAB color space coordinates (a*,b*) vary strongly with polymer thickness (FIG. 13). Over the full thickness range, AVT more than doubles and the CRI increases from 44.5 to 84.9. As a result, the LUE reaches a clear optimum at 40 nm PTB7-Th.

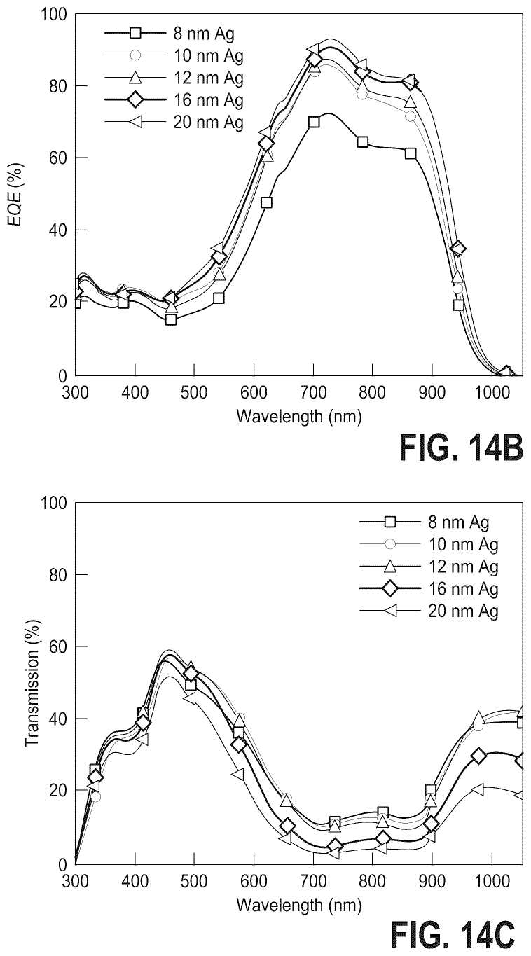

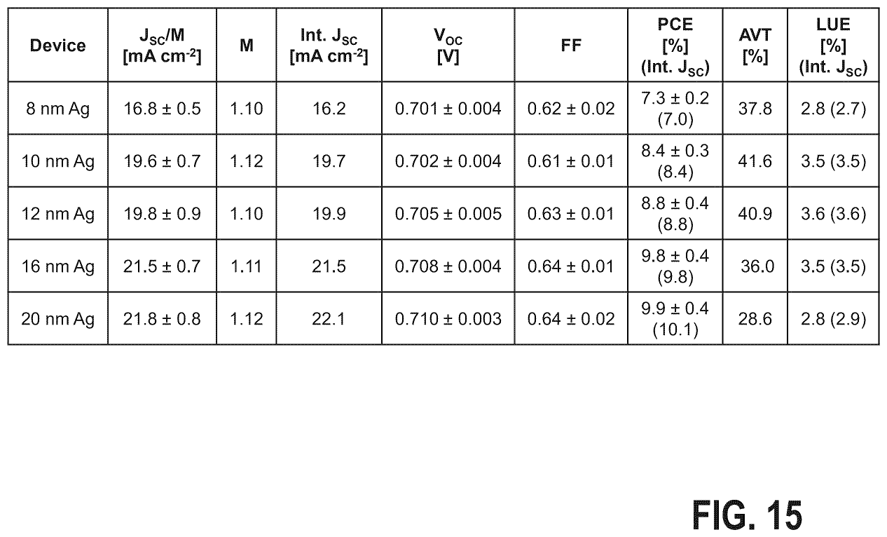

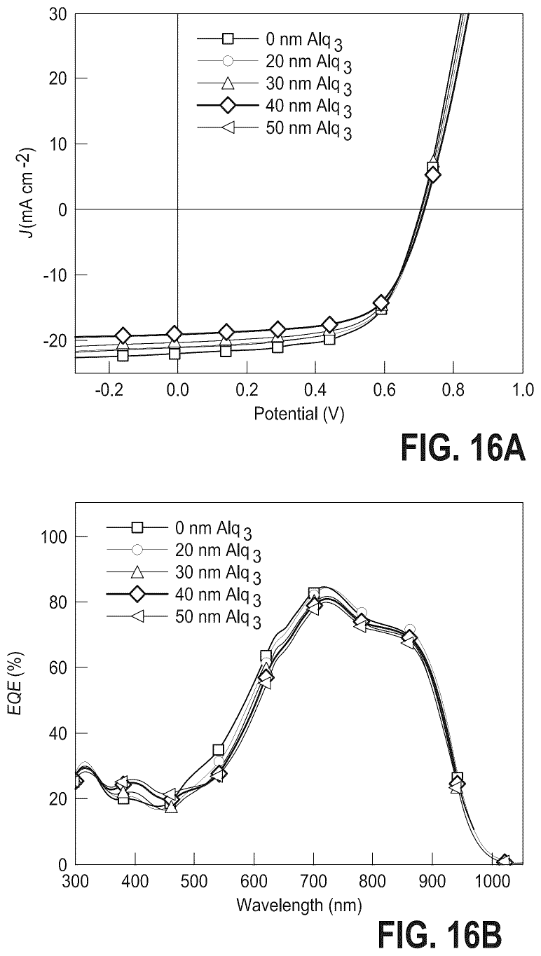

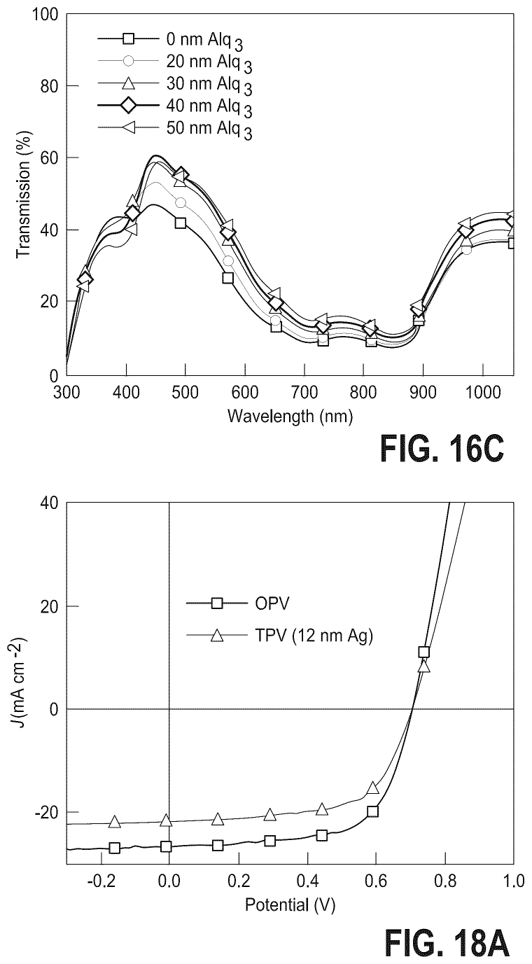

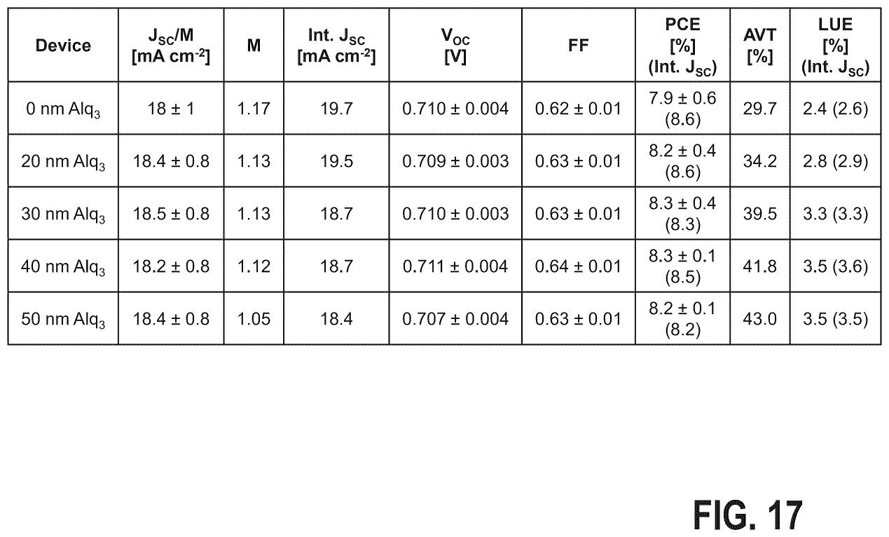

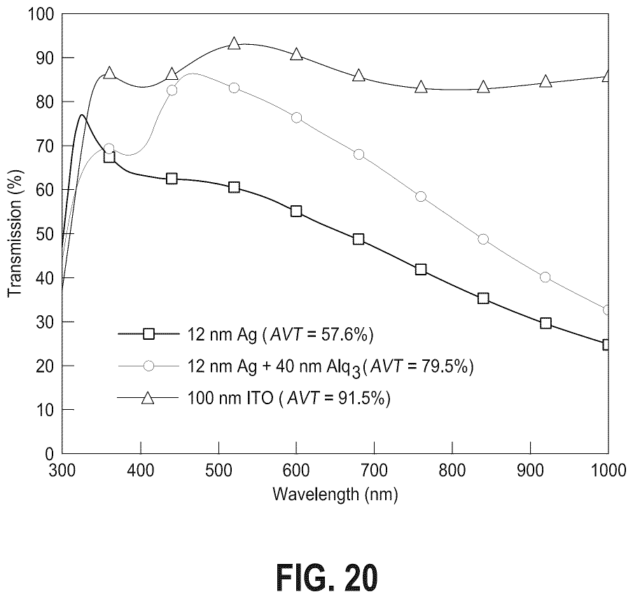

To fully optimize TPVs for electronic and optical performance, we look at the impact of thin-Ag thickness as the top transparent electrode (FIGS. 12-13) and the thickness of the antireflection layer Alq₃ (FIGS. 14-15). Ag thickness was varied from 8 to 20 nm, and all devices were made with a 40 nm Alq₃ capping layer. Small effects on the J_{SC} and FF were observed, likely due to enhanced charge carrier collection from improved conductivity of the electrode layer. Optically, an optimum Ag thickness was found at 10 nm for AVT, while the electronic and optical performances achieved a maximum at 12 nm yielding a LUE of 3.6%. Alq₃ thickness was evaluated on devices with 12 nm Ag and 35 nm PTB7-Th, and a strong effect on AVT was demonstrated, increasing from 29.7% without an Alq₃ layer to 43% with 50 nm Alq₃. The TPV PCE declines at 50 nm Alq₃ however, with an LUE of 3.5% compared 3.6% at 40 nm. While only small improvements were made to the device performance through optimization of the Ag and Alq₃ layers, they are important to reaching the excellent overall efficiencies achieved in this example of PCE=8.8%, AVT=40.9%, and LUE=3.6%, data for which is shown in FIGS. 16A-16C. A large-scale device is pictured in FIG. 17A. The electrode impact on transparency is examined using transfer matrix optical modeling and estimate that replacing the Ag/Alqs top contact with sputtered ITO would likely increase the transparency by 10% or more (FIG. 20), and lead to AVTs up to 60% for thin PTB7-Th layers.

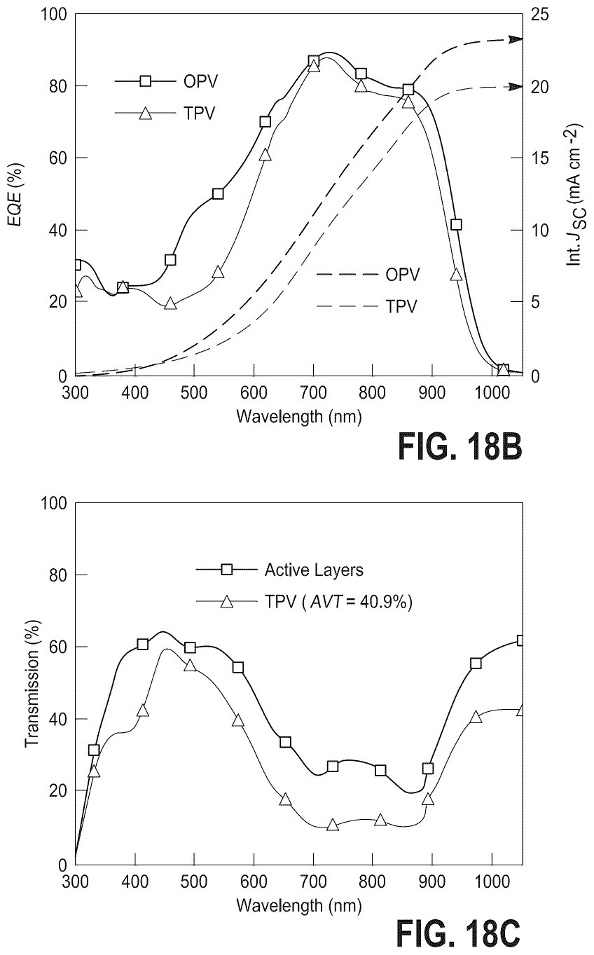

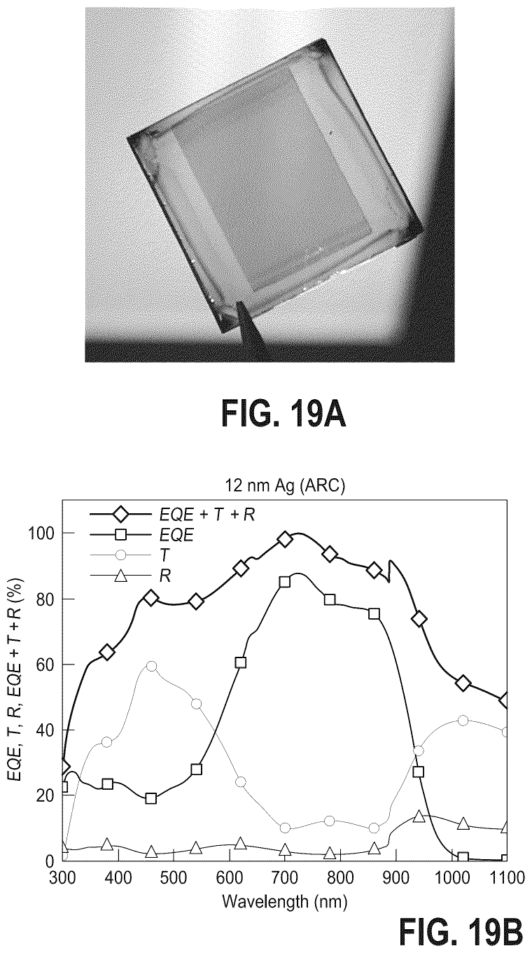

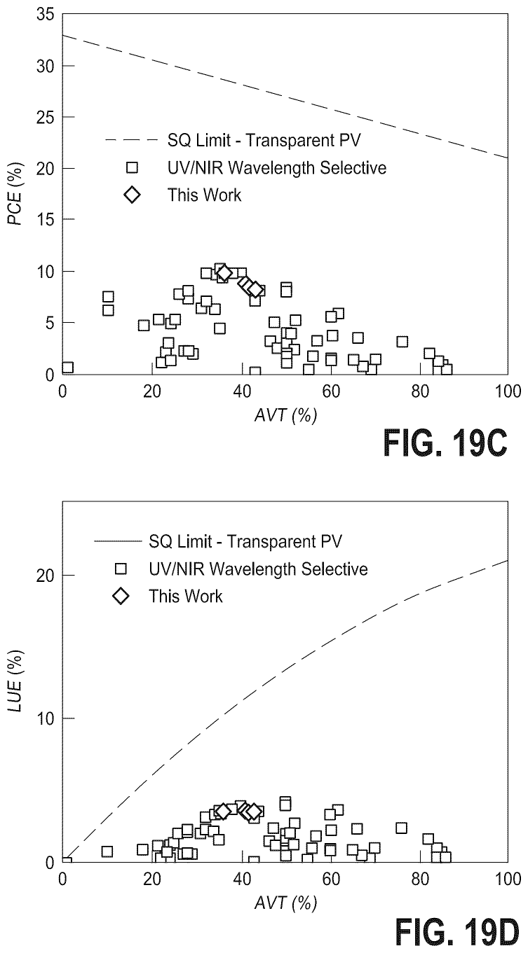

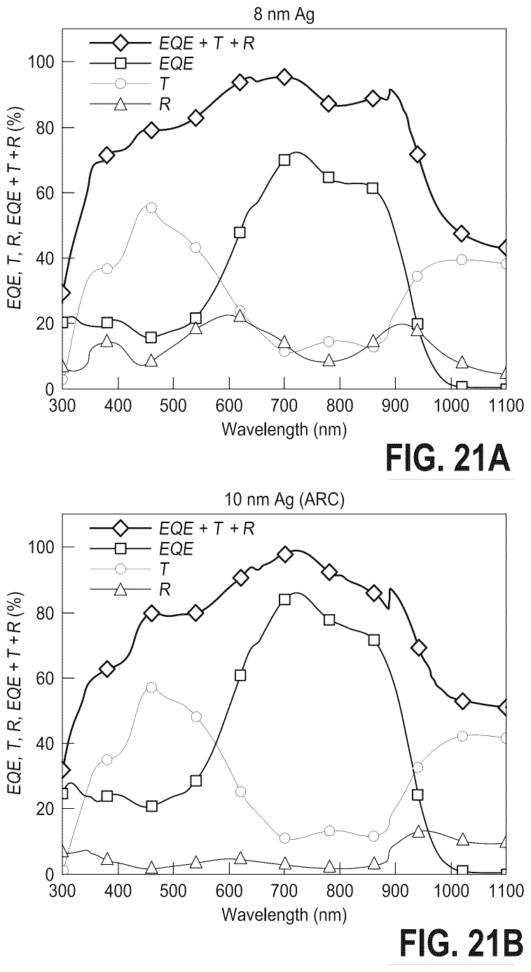

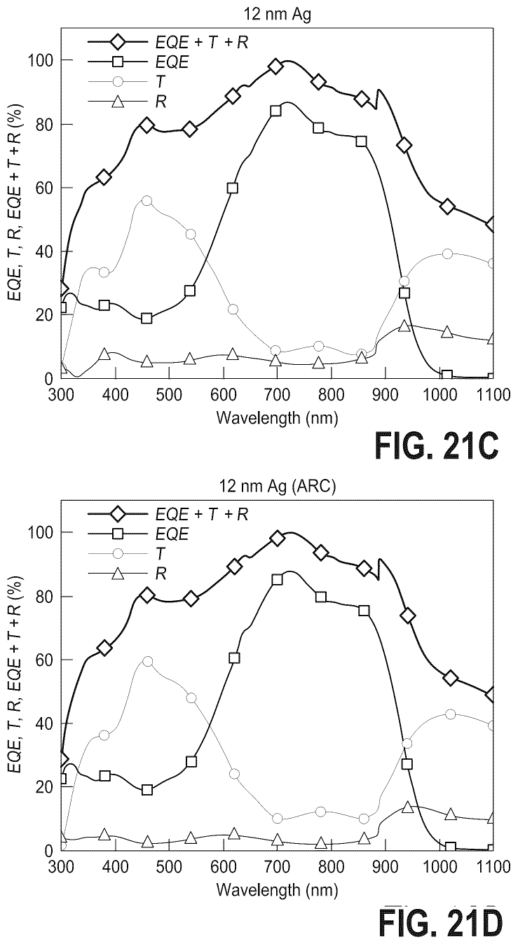

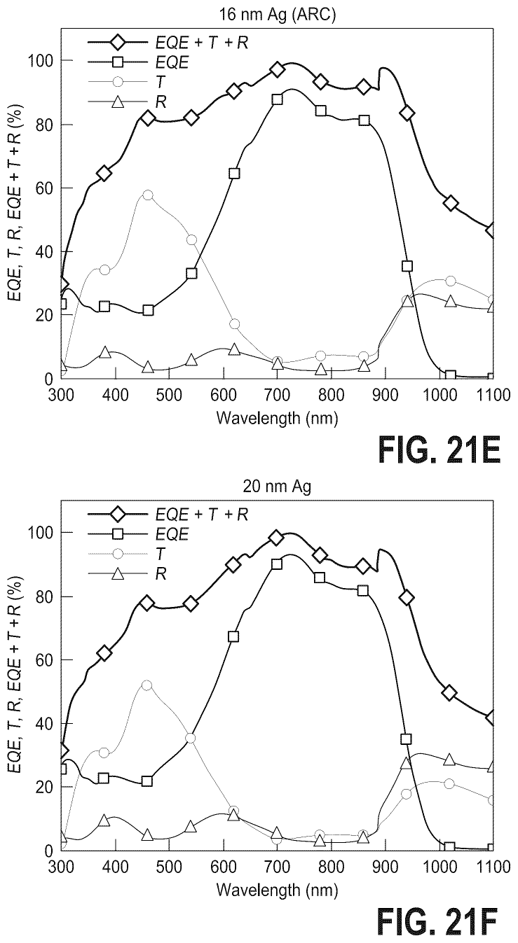

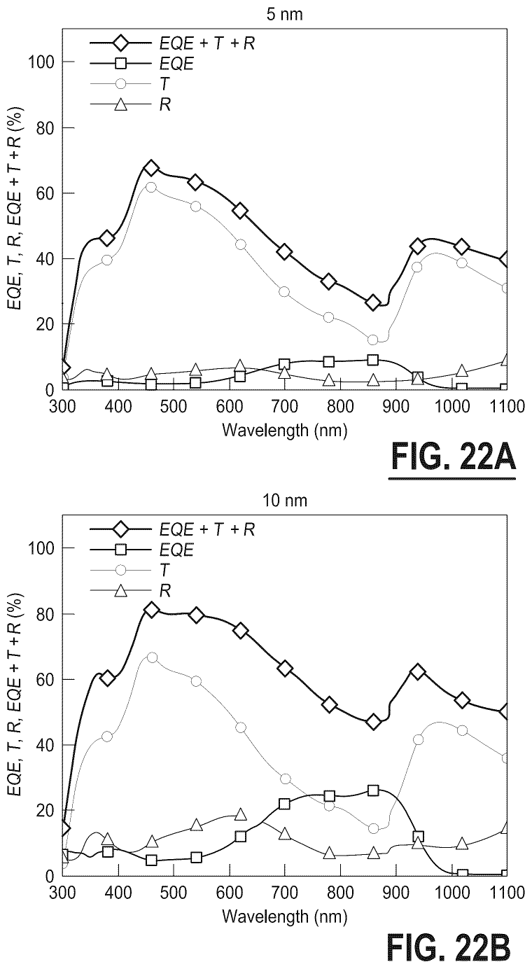

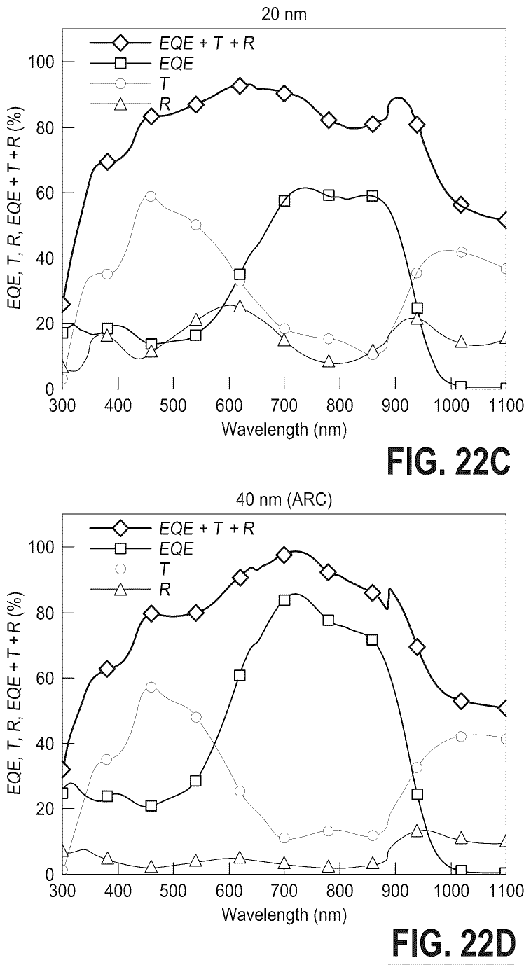

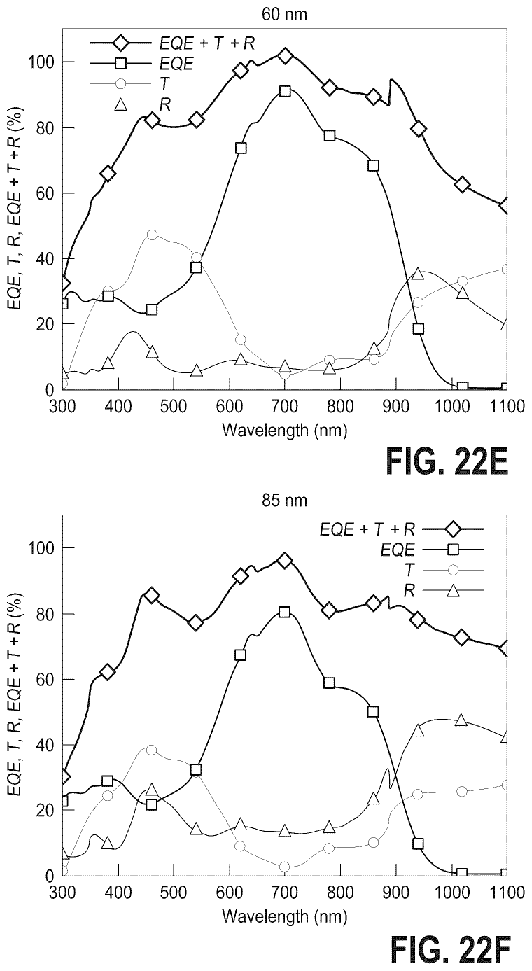

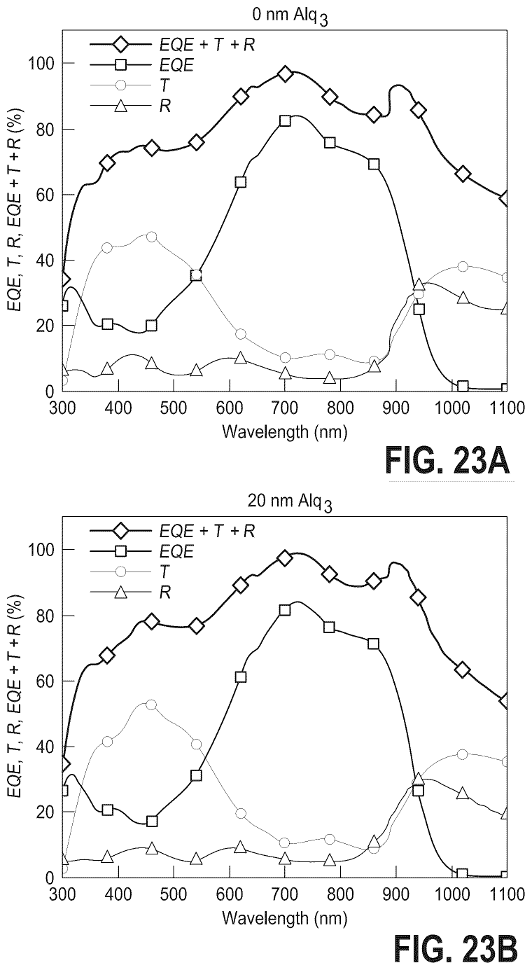

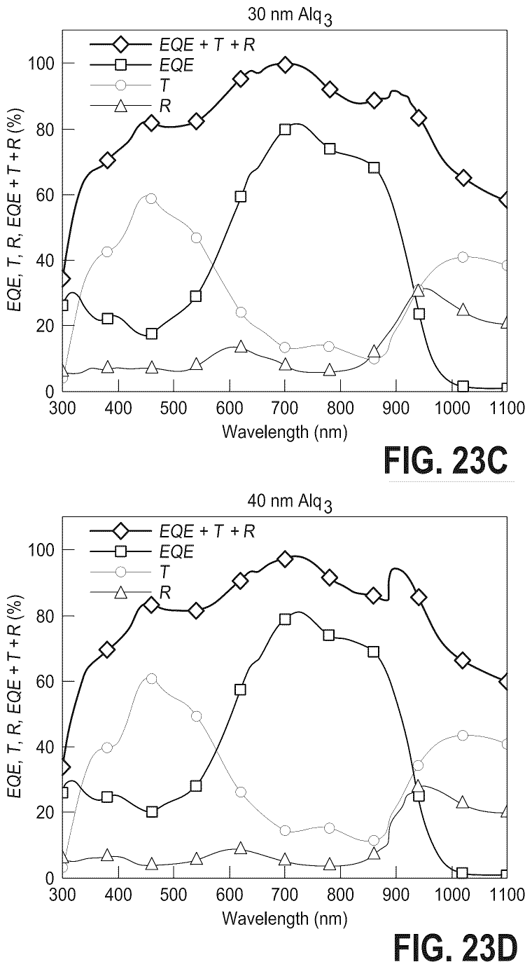

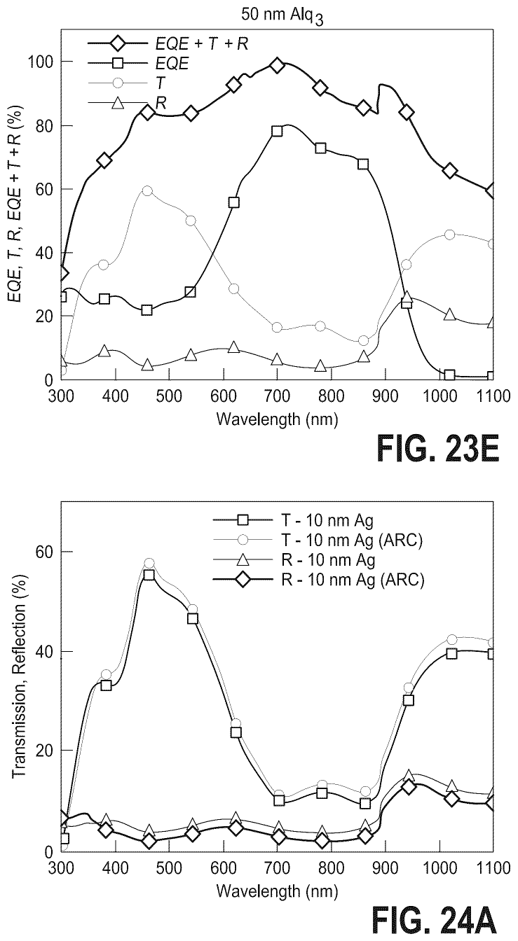

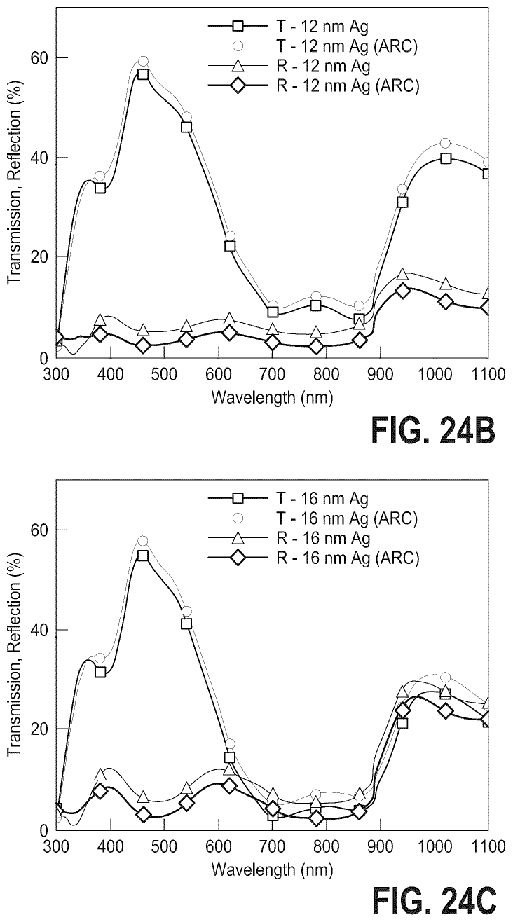

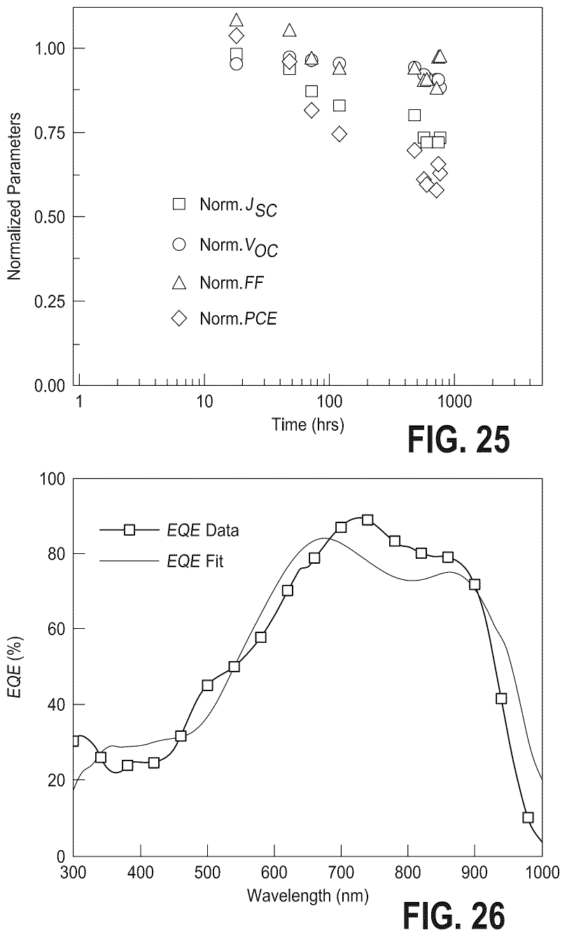

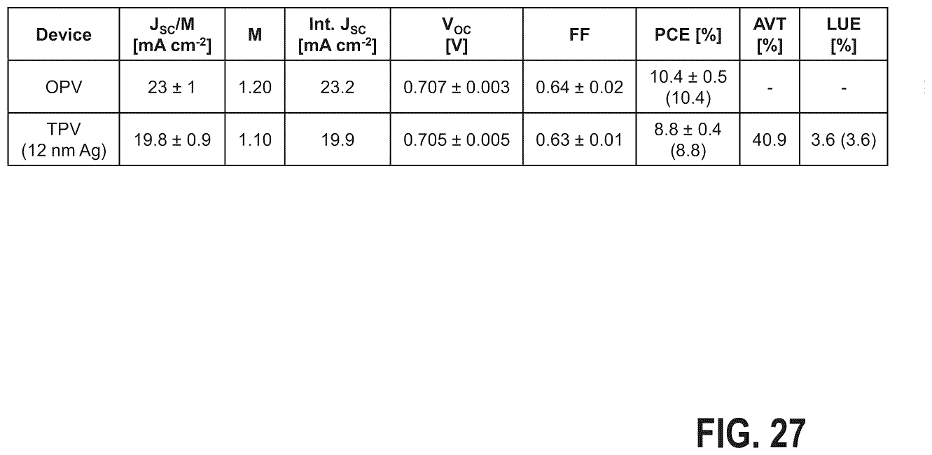

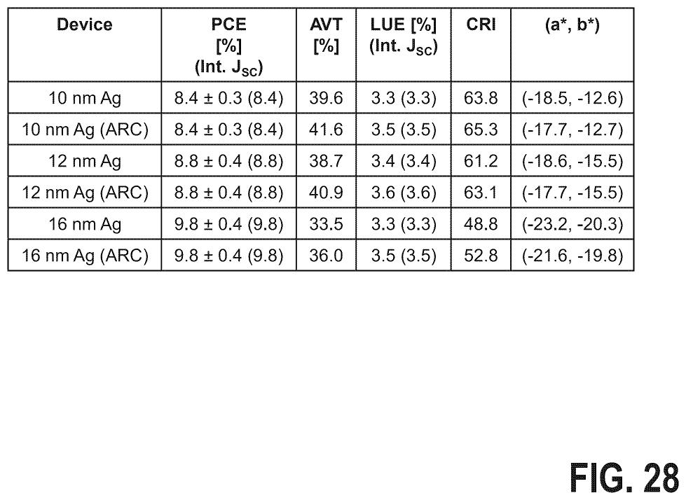

An important component of verifying any transparent solar cell is the photon balance check, where the sum of reflection (R (%)), transmission (T (%)), and EQE (as a substitute for absorption with internal quantum efficiency=1) are less than or equal to 1 at every wavelength. We provide the photon balance for our fully optimized device in FIG. 18B, and note that the balance check is satisfied and that we achieve internal quantum efficiencies (IQEs) at or above 90% for much of the NIR region. Furthermore, we provide photon balance checks for all TPVs made in this example in FIGS. 19-21. A second important verification is from the comparison of the measured J_{SC} with the integrated photocurrent from the EQE, which show excellent agreement for our devices. The impact of the ARC, observed in the low reflection achieved in FIG. 19B is detailed in FIG. 24, where the R (%) decreases and T (%) increases across the spectrum. Some of the light allowed into the device by the ARC will be absorbed on the initial pass through the device or reflected at the Ag electrode and absorbed in the reduced double pass present in TPVs. Initial lifetime measurements are reported in FIG. 25, and demonstrate that devices operate at ˜67% of the initial PCE after 1000 hours in storage.

### DISCUSSION

Optical and electronic performance are equally important in TPVs, and PTB7-Th thickness was an important parameter studied in this example in its effect on the LUE. Two important trends from the PTB7-Th thickness dependent data were the sharp loss of V_{OC} at 5 nm, and the steep and uniform drop in EQE as polymer thickness decreased from 40 nm to 5 nm.

The sharp V_{OC} cutoff at 5 nm PTB7-Th indicates that ˜10 nm is sufficient to form a neat layer that remains intact after spin-coating IEICO-4F. Neat films that remain intact following sequential spin-coating have been demonstrated via high-resolution cross-sectional tunneling electron microscopy. Devices have been produced with PCE>17% using a protective solvent layer to reduce mixing and produce high purity domains, suggesting that high efficiency devices are possible with little to no mixed region. Exciton diffusion lengths of NFAs, measured with EQE quenching and transient absorption spectroscopy of exciton annihilation, are sufficient to support a bilayer infrastructure with a thin (NFA<50 nm) layer. However, many LBL demonstrations have concluded that significant intermixing occurs via swelling of the polymer film during NFA deposition to form a mixed region of varying size within the planar heterojunction. We explain the V_{OC} drop at 5 nm as the result of an incomplete film of PTB7-Th allowing for a continuous path of IEICO-4F in parts of the structure from ZnO to MoO₃. The low J_{SC} produced from the 5 nm PTB7-Th device is the result of exciton dissociation likely from any remaining islands of PTB7-Th where a dissociating HJ still exists. Thus, the polymer thickness demonstation suggests that up to 5 nm of the PTB7-Th can be dissolved during the IEICO-4F deposition, which could result in the intermixed region of approximately 5 nm between layers of PTB7-Th and IEICO-4F. Ideal diode parameters (FIG. 9) from fitted dark J-V curves as a function of PTB7-Th thickness (FIGS. 8F and 6A-6B) reveal decreased R_{P}, and increased R_{S} and n_{id} as polymer thickness decreases from 40 nm to 5 nm. Conceptually, decreased R_{P} causes increased shunting resulting in current loss and a voltage drop by creating an alternate pathway for current so that a partial junction and resistor are formed in parallel. Increased n_{id} above 1.5 indicates more trap-assisted recombination. This conclusion is consistent with the light intensity (P₀) dependence of the V_{OC} (FIGS. 8E and 10A) and J_{SC} (FIG. 12B). V_{OC} is related to P₀ by Eq. 1, with the Boltzmann constant (k_{B}), temperature (T), and elementary charge (q).

$${V}_{O C} ∝ \frac{{k}_{B} T}{q} ln ( {P}_{0} ) \qquad Eq . 1$$

The magnitude of the slope of V_{OC} vs ln(P₀) signifies the dominant mode of recombination in the device. A slope approaching k_{B}T/q indicates bimolecular recombination controls the recombination process of charge carriers, and a slope of 2k_{B}T/q points towards increased monomolecular or trap-assisted recombination. Relatively small changes are observed in the slope as polymer thickness changes from 10 to 85 nm, however a clear minimum is reached at 40 nm PTB7-Th. The magnitude of this shift in slope is comparable to that observed when CN is added, indicating a similarly strong effect that we also observed in the EQE. The exponent of a power law relationship between J_{SC} and P₀ (Eq. 2) describes the relative amount of bimolecular recombination in a device, with s approaching 1 indicative of less bimolecular recombination:

$${J}_{SC} ∝ {P}_{0}^{s} \qquad Eq . 2$$

No clear trend is observed in the value of s as polymer thickness changes, from which we conclude that all devices have similar amounts of bimolecular recombination. V_{OC} vs P₀ trends then suggest that as the polymer thickness deviates from 40 nm (smallest slope), trap-assisted recombination increases in prevalence, in good agreement with the dark J-V trends.

To provide a framework for our analysis of the PTB7-Th thickness dependent EQE trends, we describe the EQE in Equation 3 as the product of five component efficiencies for absorption (η_{A}), exciton diffusion (η_{ED}), charge transfer (η_{CT}), exciton dissociation (η_{DS}), and charge collection (η_{cc}).

$$E Q E = {η}_{A} {η}_{E D} {η}_{C T} {η}_{D S} {η}_{C C} \qquad Eq . 3$$

Decreased polymer absorption at 5 nm PTB7-Th explains the significant photocurrent loss in the short NIR, VIS, and UV regions, but not the loss of EQE from IEICO-4F. From FIG. 10C, minimal changes are seen in the IEICO-4F absorption as polymer thickness changes, indicating that the EQE reduction is at least partially caused by an electronic effect. Optical interference effects from changing the PTB7-Th thickness could cause a shift in the electric field strength and exciton generation rate at specific locations in the IEICO-4F film. Generating excitons closer to the polymer-NFA interface will enhance the rate of successful exciton diffusion to the interface by decreasing the path length, increasing nED. However, exciton generation rate will also vary spectrally based on the wavelength, and the uniform relative drop in EQE across the entire spectrum from 300 to 900 nm in both PTB7-Th and IEICO-4F is a strong indication of an electronic limitation in the device. Changes in the heterojunction formed can alter the remaining efficiencies that make up the EQE. Charge transfer and exciton dissociation require a favorable energetic offset between PTB7-Th and IEICO-4F that allows for the electron or hole of the exciton to move across the interface (η_{CT}) and the energetic offset to overcome the exciton binding energy and dissociate the exciton into free charge carriers (η_{DS}). For a heterojunction that is spatially uniform across the entire device, there is typically either a sufficient energetic offset to yield high η_{CT} and η_{DS} or there is not, and the device effectively turns off. We do not observe this binary effect in our devices, as the photocurrent steadily drops from 40 nm to 20, 10 and 5 nm PTB7-Th. Exciton diffusion is also an interface dependent parameter from the standpoint of 1) the location of exciton generation relative to the interface (optical interference related effects) and 2) the shape and overall area of the PTB7-Th:IEICO-4F interface (morphology effects). Reduced η_{ED} from IEICO-4F could explain the low photocurrent in the 800-1000 nm range. Last, charge collection is affected by the PTB7-Th:IEICO-4F interface in that carriers generated at the interface should travel to the MoO₃ layer (holes) through IEICO-4F or to the ZnO layer (electrons) through PTB7-Th. The longer the path length for carriers to travel, the lower the charge collection efficiency given identical carrier mobility and lifetime. The IEICO-4F layer was formed at the same concentration and spin rate, so that the thickness should not change even as the PTB7-Th layer becomes thinner and η_{cc} should not decrease substantially barring morphology changes that effect carrier properties. Charge collection through the PTB7-Th should become more efficient with a shorter path length. Similar to our discussion of η_{CT} and η_{DS}, charge collection behaves in a much different manner if the PTB7-Th:IEICO-4F heterojunction is not uniformly present. The decrease in EQE at 5 nm PTB7-Th can be explained by the changes to the HJ discussed above, while the EQE drop from 40 nm to 10 nm, is attributed to a combination of decreased PTB7-Th absorption and less efficient exciton diffusion in the IEICO-4F layer as a result of optical interference changes. While 10 nm PTB7-Th is required to maintain the V_{OC}, we also show that 20 nm PTB7-Th is suitable for the FF and still produces a PCE>6%. The LBL approach allows thinner polymer layers to be used without critically hampering the heterojunction, evidenced by the high FF at 20 nm. The benefit of a thin PTB7-Th layer is also important in the optical evaluation of the device.

Three important parameters to evaluate for optical quality are the AVT, CRI, and (a*, b*). AVT describes the overall transparency of the device relative to human perception, with values less than 50% typically resulting in colored, reflective, or strongly tinted TPVs. AVT>60% will generally look clear and is considered acceptable for many transparent applications. CRI captures how accurately the true color of an object observed through the device is rendered, with CRI>80 considered acceptable. The color chromaticity coordinates (a+, b*) define the specific color tint, with a desired range of −15<a*<1 and −15<b*<15 in glass and glazing industries for tinted products and −7<a*<0 and −3<b*<7 for mass-market architectural glass products. We note that TPVs with yellow or red tint (a* and/or b*>0) are less appealing for glass products than those with a neutral or blue/green tint (negative values of a* and b*). Aesthetically, PTB7-Th thickness is important to the optical quality of the devices, where >20 nm PTB7-Th results in low AVT (<50%), and a CRI of 63 for the improved device as well as (a*,b*) outside of the desired range. This is visually evident from the device picture in FIG. 19A, where the relatively strong PTB7-Th absorption of 550 to 675 nm light gives the devices a strong blue color. Shifting the polymer thickness from 40 nm to 20 nm moves the TPVs into an acceptable range of color space coordinates for many window applications. The CRI and AVT reach 82.8 and 50.4%, clearing industry standards at 10 nm PTB7-Th. Utilizing 5 nm of PTB7-Th, the CRI and (a*, b*) approach desired ranges for glass products. The strong effect of polymer thickness on optical performance illustrates the utility of the LBL approach.

LBL deposition of the active layers clearly defines the location and role (acceptor or donor) of each material in the device stack. This allows for transfer matrix optical modeling to be used to extract exciton diffusion lengths (LED) for both materials via a nonlinear regression fit of the calculated EQE to the measured EQE. An example fit is shown in FIG. 26. An LED of 120 nm was extracted for PTB7-Th, while the LED for IEICO-4F was 140 nm. The magnitude of LED for both active materials emphasizes the effectiveness of the LBL approach for device fabrication.

To provide context, we present a comparison of the device performance produced in this example to other wavelength selective single heterojunction devices in 17C-17D. Our devices achieve good PCE, AVT, and LUE compared to the current state of the TPV field. Notably, while many TPVs have reached 7-10% PCE with moderate AVT, only a few have demonstrated LUE of 3 or higher but mostly with notably poor CRI. Looking forward, improving optical performance while maintaining electronic performance is an important areas of focus. There are two primary routes to improving optical performance by 1) minimizing parasitic absorption from the electrodes with more transparent but equally conductive materials, such as with ITO replacing the Ag/Alq₃ anode, and 2) altering the PTB7-Th polymer to reduce visible absorption. Chemical modification of the PTB7-Th monomer core to red shift the absorption is one route to achieving better optical performance while maintaining the morphology of PTB7-Th:NFA devices. Alternatively, several polymers with deeper NIR absorption have been demonstrated, including DPP2T which maintained an excellent V_{OC} of 0.75 V in a BHJ. Reduced energetic losses will be required to maintain the V_{OC} with a narrower bandgap polymer, and less visible light harvesting will always come at the cost of photocurrent if improvements are not made to the IQE, which is possible if the reduced active layer thickness leads to enhanced exciton diffusion and charge collection efficiencies. Absorption sets a limit on the current production at a given wavelength so there likely should be photocurrent loss from the visible to achieve the higher optical performance required for many applications of TPVs.

Additionally, we note the high PL QY of these compounds likely plays an important role in the high performance by reducing non-radiative recombination. The measured QY of IEICO-4F is 20% and the QY of PTB7-Th is 3%.

### CONCLUSION

In this example we present high performance solution processed LBL deposited TPVs based on an uncommon donor-acceptor architecture. In addition, we demonstrate a complete demonstration of the impact of polymer (acceptor) thickness on power generation and aesthetic performance. We find that the LBL approach enables exciton diffusion lengths of 120 nm and 140 nm for PTB7-Th and IEICO-4F, highlighting the strength of the planar HJ formed as a result of sequential deposition processing. An improved or optimized PCE and AVT of 8.8% and 40.9% is achieved, yielding an LUE of 3.6% comparable to the best TPV demonstrations to date. Given the neat polymer acceptor layer thickness dependence we find evidence for the formation of a 5 nm mixed region. Optically, thinner layers of polymer move the devices from an unappealing optical regime to one that is acceptable for many applications with AVT>50% and CRI>80. Future work for LBL TPVs should focus on improving the optical performance of these devices to push the AVT and CRI to acceptable levels while maintaining PCE>8%. The impact of polymer thickness on device performance that we reveal here paves the way for future transparent PVs to use this design approach to effectively balance power generation and aesthetic quality. Overall, these devices demonstrate the power of the LBL approach for transparent solar technologies via unique control over active layer thicknesses, architecture design, and optimization that could ultimately aid in the scaleup of these devices.

### Experimental

Active layer and ZnO solution preparation: PTB7-Th (1-Material) was dissolved in o-xylene (Sigma Aldrich) at 1-10 mg mL⁻¹ and covered, stirred, and heated at 70° C. overnight. IEICO-4F (1-Material) was dissolved in o-xylene:n-butanol: 1-chloronaphthalene (Sigma Aldrich) at 75:25:0, 74.25:24.75:1, 73.5:24.5:2, 72.75:24.25:3, 72:24:4, 71.25:23.75:5, and 70.5:23.5:6 v/v ratios to yield 1-chloronaphthalene doping of 0 to 6%. IEICO-4F solutions were then covered, stirred, and heated at 70° C. overnight. ZnO solutions were prepared with 1 g zinc acetate dihydrate (Sigma Aldrich), 0.277 mL ethanolamine (Sigma Aldrich), and 10 mL 2-methoxyethanol (Sigma Aldrich), and covered and stirred rigorously overnight in a fumehood.

Device fabrication: Pre-patterned ITO coated glass substrates were cleaned via sequential sonication for 10 minutes each in deionized water, acetone, and isopropanol. Substrates were dried on a hotplate at 135° C. for 1 minute and then plasma cleaned under light vacuum for 10 minutes. The ZnO layer was spin-coated onto the substrates immediately after plasma cleaning for 30 s at 4000 rpm (50 μL, 2000 rpm/s acceleration). ZnO covered substrates were annealed at 200° C. for 20 minutes in air prior to moving to a glovebox for active layer spin-coating. PTB7-Th films were spun using 65 μL at 1000 rpm for 15 s and 2000 rpm for 5 s to yield thicknesses ranging from 5-85 nm as measured by variable angle spectroscopic ellipsometry (VASE). Films were spun on silicon wafers for VASE measurements. IEICO-4F films were spun at 1500 rpm for 45 s (60 μL solution) to yield films of approximately 55 nm (VASE). After sequential bilayer deposition, devices were annealed at temperatures ranging from room temperature to 150° C. for 10-20 minutes. Substrates were then loaded into a high vacuum thermal vapor deposition chamber (Angstrom Engineering) where 7 nm of MoO₃ was deposited at 3×10−6 torr. Finally, a top contact of Ag (opaque devices-80 nm) or Ag and Alq₃ (TPVs) was deposited using a special mask to define an active area of 4.43 mm². For TPVs, Ag thickness (measured with AFM) ranged from 8 to 20 nm and Alq₃ thickness (VASE) from 0 to 50 nm.

Device Testing: Current-voltage (J-V) characteristic curves were measured with a Keithley 2420 SourceMeter under illumination from a Xe Arc lamp calibrated to 1-sun intensity with a NREL-calibrated Si reference cell with KG5 filter. A minimum of 5 devices were tested for each condition. EQE measurements were made with monochromated light from a tungsten halogen lamp chopped at 200 Hz. A Newport-calibrated Si diode was used to calibrate the system prior to taking EQE measurements. For each structure with distinct EQE, the spectral mismatch factor, M, was calculated from Equation 4, where E_{Ref} is the reference spectral irradiance (AM1.5G), E_{S} is the source spectral irradiance (Xe Arc lamp), S_{R} is the reference spectral responsivity (Newport-calibrated Si diode), and S_{T} is the device spectral responsivity (device EQE):

$$M = \frac{{\int }_{{λ}_{1}}^{{λ}_{2}} {E}_{Ref} ( λ ) {S}_{R} ( λ ) d λ}{{\int }_{{λ}_{1}}^{{λ}_{2}} {E}_{Ref} ( λ ) {S}_{T} ( λ ) d λ} \frac{{\int }_{{λ}_{1}}^{{λ}_{2}} {E}_{S} ( λ ) {S}_{T} ( λ ) d λ}{{\int }_{{λ}_{1}}^{{λ}_{2}} {E}_{S} ( λ ) {S}_{R} ( λ ) d λ} \qquad Eq . 4$$

Dark J-V curves were taken with the device holder covered and all light sources turned off. Light intensity (P₀) dependent J-V curves were taken with four different neutral density filters placed between the Xe Arc lamp and the device. Note that the mismatch was also corrected for each filter. Dark J-V fitting (photocurrent, Jₚₕ=0) of the ideal diode equation (Eq. 5) was performed using MATLAB to extract device parameters:

$$J = \frac{{R}_{P}}{{R}_{S} + {R}_{P}} \{ {J}_{0} [ exp ( \frac{q ( V - {JR}_{S} )}{{n}_{i d} {k}_{B} T} ) - 1 ] + \frac{v}{{R}_{P}} \} - {J}_{p h} \qquad Eq . 5$$

Optical performance assessment: Un-patterned ITO coated glass substrates were used to prepare device stacks for optical characterization. Optical devices were fabricated simultaneously with electronic PVs to ensure the same device conditions but without the patterned mask defining the top contact (Ag and Alq₃). A dual-beam Perkin Elmer Lambda 900 UV/VIS/NIR Spectrometer was used in transmission mode to measure the transmittance and reflectance of TPVs. The reference side was kept empty for all thin film measurements and devices were placed so that all incident light passed through the sample. Reflectance measurements were made with a 6° specular accessory installed on the sample side. Optical figures of merit including AVT, CRI, and (a*,b*) were calculated from transmittance data using the available spreadsheet. For 1-chloronapthalene doping level optimization, optical samples were complete after deposition of the PTB7-Th and IEICO-4F active layers. For PTB7-Th thickness optimization, optical samples for transmittance characterization of just the PTB7-Th layer were complete after depositing PTB7-Th on ZnO and ITO covered glass substrates. Full devices with various PTB7-Th thickness were prepared for determination of the optical figures of merit.

Shelf-life assessment: Large area devices (27 mm²) were fabricated in the same manner as smaller devices for the optimal TPV (12 nm Ag, 40 nm PTB7-Th, 40 nm Alq₃ and 4% CN) and encapsulated with a getter pad using a UV-curable epoxy (DELO). Devices were stored in the dark in an oxygen and moisture free environment and were temporarily placed in atmospheric conditions for J-V testing under 1-sun illumination from a Xe Arc lamp. J-V data was normalized to the fresh device performance.

### Example 2

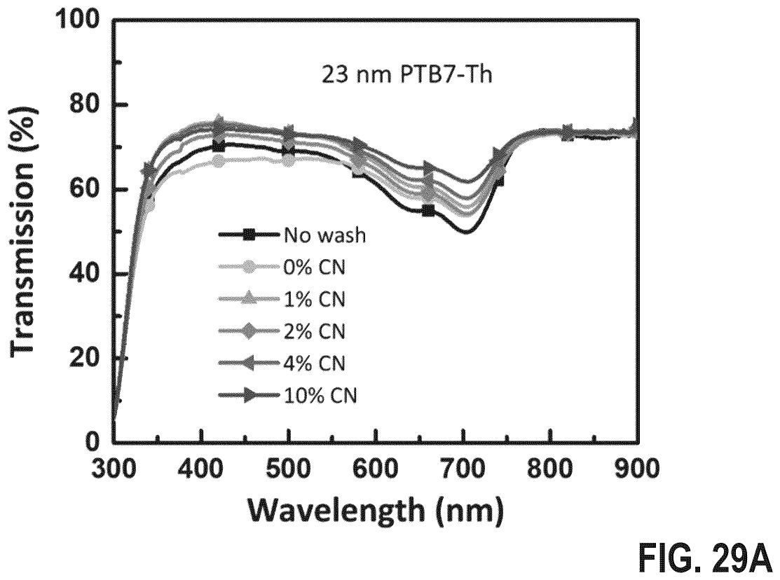

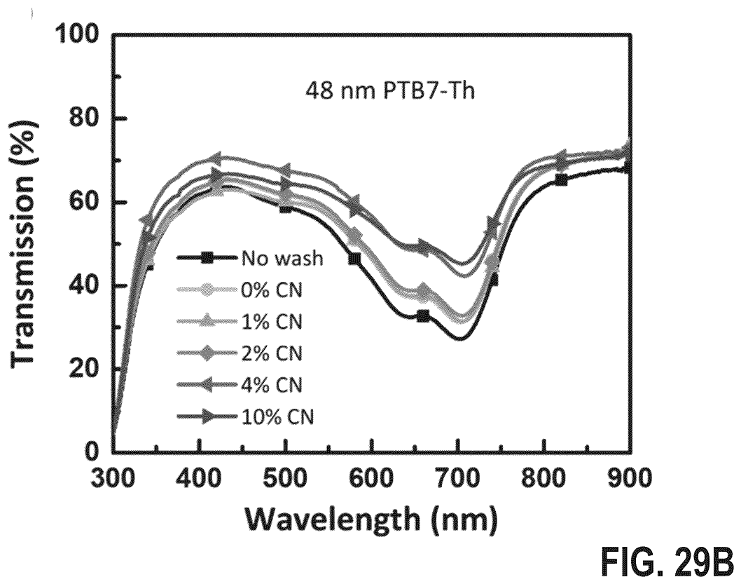

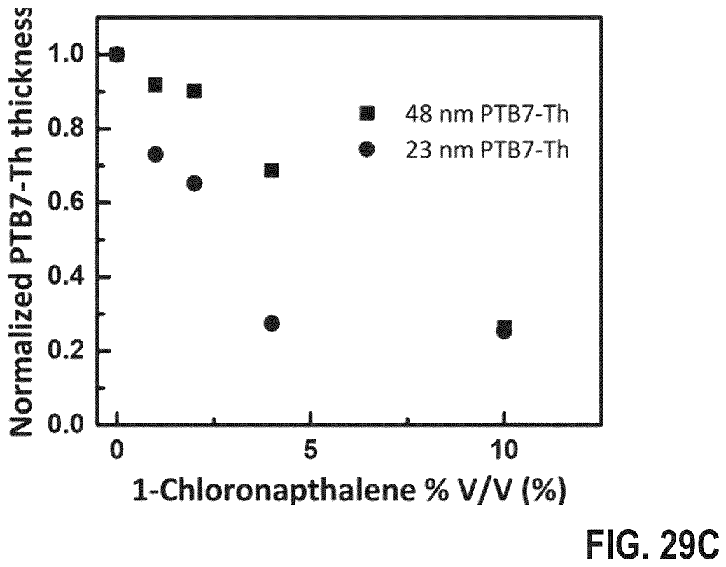

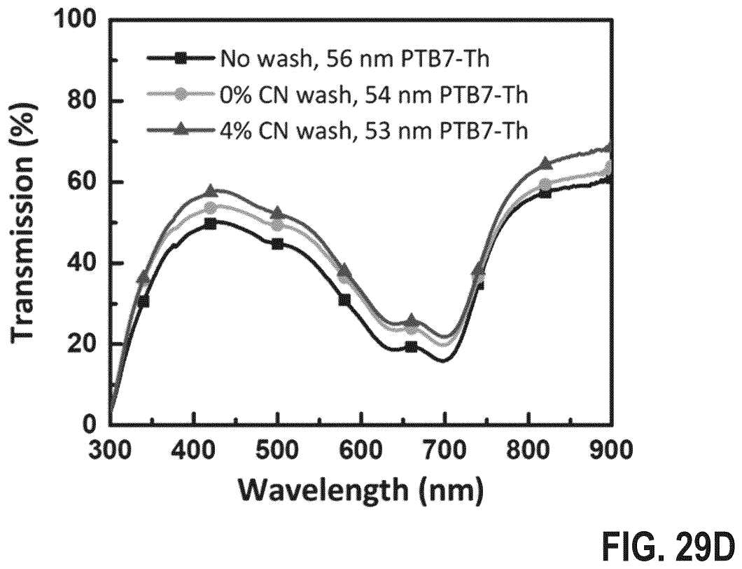

FIGS. 29A-29D relate to solvent orthogonality for PTB7-Th in accordance with at least some example embodiments.

FIG. 29A illustrates transmission data for 23 nm PTB7-Th films without a second spin-coating wash step and with a spin-coating wash with varying amounts of 1-chloronaphthalene (CN). FIG. 29B illustrates transmission data for 48 nm PTB7-Th films without a second spin-coating wash step and with a spin-coating wash with varying amounts of 1-chloronaphthalene (CN). FIG. 29C illustrates normalized thickness of PTB7-Th films after a spin-coating wash with varying amounts of CN corresponding to the transmission data in FIGS. 29A-29B. FIG. 29D illustrates transmission data for a PTB7-Th films without a second spin-coating wash step and with a wash spin containing 0 or 4% CN. The wash solutions in the example of FIG. 29D containe o-xylene/n-butanol/ethyl benzene/CN at 73.5/25/1.5/0 (0% CN) or 70.5/24/1.5/4 (4% CN).

### Example 3

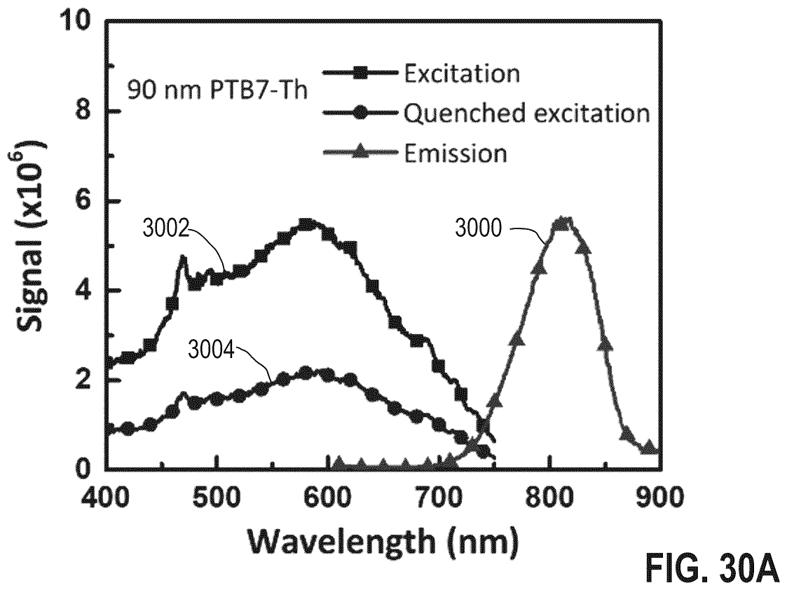

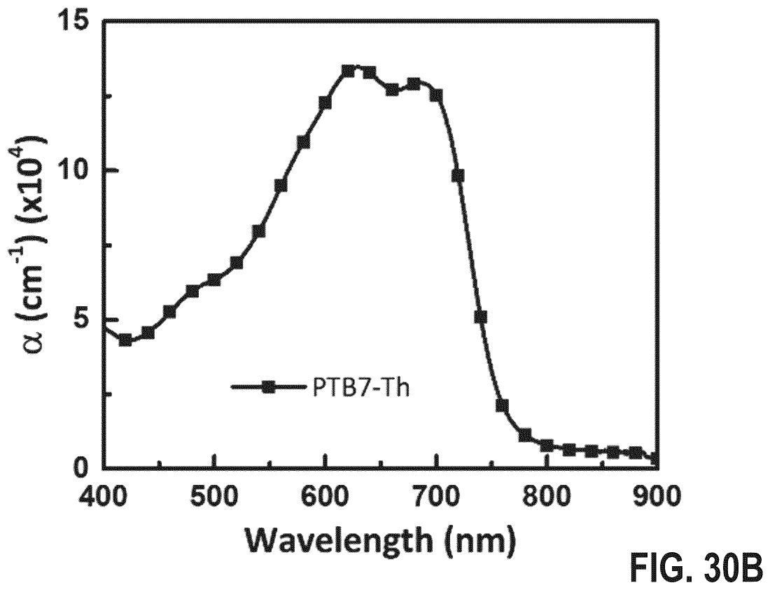

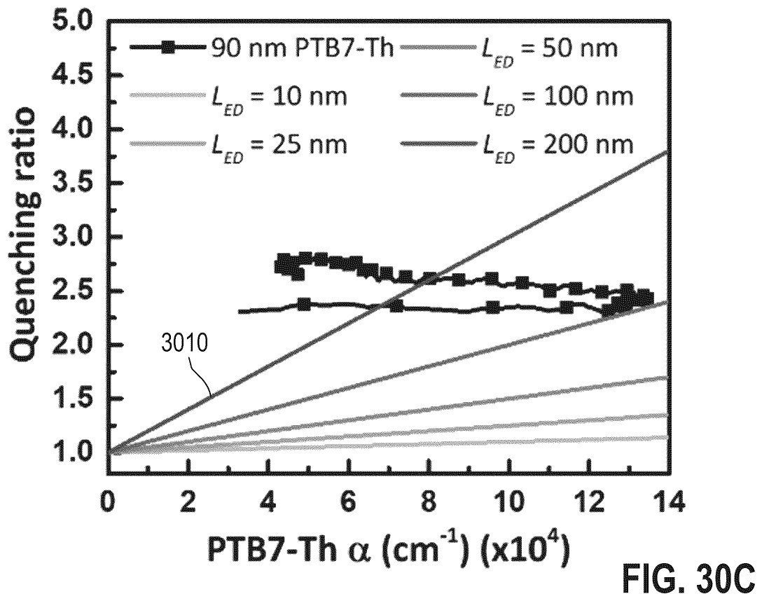

FIGS. 30A-30C relate to spectrally resolved photoluminescent quenching for polymer films in accordance with at least some example embodiments.

FIG. 30A illustrates excitation scans of 90 nm PTB7-Th films emitting at 810 nm (3000) without (3002) and with (3004) a 10 nm PCBM quenching layer present. FIG. 30B illustrates extinction coefficient of PTB7-Th as a function of wavelength. FIG. 30C illustrates the ratio of photons emitted by PTB7-Th without a quenching layer to photons emitted with a quenching layer for 90 nm PTB7-Th films on glass as a function of extinction coefficient (3010). The predicted quenching ratio as a function of exciton diffusion length is included, indicating the lack of sensitivity in the experimental data to the molecular extinction coefficient and indicating the diffusion length is greater than the thickness of the film (>90 nm).

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A transparent photovoltaic device comprising:
a substrate;
a first electrode on the substrate;
a second electrode; and
a plurality of planar photoactive layers between the first electrode and the second electrode, wherein the device has a largest absorption peak of less than 430 nm or greater than 650 nm.

2. The transparent photovoltaic device of claim 1, wherein at least one of the plurality of planar photoactive layers has an exciton diffusion length of greater than 50 nm.

3. The transparent photovoltaic device of claim 2, wherein all of the plurality of planar photoactive layers have an exciton diffusion length of greater than 50 nm.

4. The transparent photovoltaic device of claim 1, wherein at least one of the plurality of planar photoactive layers has a charge collection length of greater than 50 nm.

5. The transparent photovoltaic device of claim 4, wherein all of the plurality of planar photoactive layers have a charge collection length of greater than 50 nm.

6. The transparent photovoltaic device of claim 1, wherein the plurality of planar photoactive layers includes,
a donor layer including a first photoactive material, and
an acceptor layer including a second photoactive material.

7. The transparent photovoltaic device of claim 6, wherein
the first photoactive material includes a polymer, a non-fullerene acceptor, a small molecule, or any combination thereof, and
the second photoactive material includes a polymer or a small molecule.

8. The transparent photovoltaic device of claim 7, wherein the first photoactive material includes the polymer.

9. The transparent photovoltaic device of claim 8, wherein the polymer is selected from the group consisting of PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof.

10. The transparent photovoltaic device of claim 7, wherein the first photoactive material includes the non-fullerene acceptor.

11. The transparent photovoltaic device of claim 10, wherein the non-fullerene acceptor is selected from the group consisting of ITIC, Y6 (BTP-4F), ITIC-4F, ITIC-2F, ITIC-4CI, ITIC-M, ITIC-M, ITIC-Th, IDIC-4F, N3, BTP-4F-12 (Y6-BO), DTY6, IEICO-4F, IEICO-4CI, BTP-eC9, eC9-2CI, Y7, BTP-4CI-12, TPT-10, TPT10-C8C12, IDT-2Br, COTIC-4F, COTIC-4CI, IHIC, 6TIC, FBR, o-IDTBR, IO-4CI, L8-BO, L8-BO-F, ZY-4CI, COi8DFIC (O6T-4F), BODIPY, or any combination thereof.

12. (canceled)

13. The transparent photovoltaic device of claim 7, wherein the second photoactive material includes the polymer.

14. The transparent photovoltaic device of claim 13, wherein the polymer is selected from the group consisting of PTB7, PTB7-Th, DPP-DTT, PDPP3T, PDPP4T, PffBT4T-2OD, PffBT4T-C9C13, PBDB-T, PDBD-T-SF, PBDB-T-2CI, PBDB-T-2F, PBDD4T, PBDD4T-2F, PBDTT-DPP, PBDTTPD, PBDTTTPD, PCDTBT, PDPP4T-2F, DPP2T, PJ71, J52, D18, or any combination thereof.

15. (canceled)

16. The transparent photovoltaic device of claim 6, wherein
the donor layer and the acceptor layer are in direct contact,
the donor layer is substantially free of the second photoactive material, and
the acceptor layer is substantially free of the first photoactive material.

17. (canceled)

18. The transparent photovoltaic device of claim 6, wherein one of the first photoactive material and the second photoactive material has a quantum yield of greater than or equal to 15% and the other of the first photoactive material and the second photoactive material has a quantum yield of greater than or equal to 2%.

19. The transparent photovoltaic device of claim 6, wherein
the first photoactive material has a first quantum yield,
the second photoactive material has a second quantum yield, and
a sum of the first quantum yield and the second quantum yield is greater than or equal to 20%.

20. The transparent photovoltaic device of claim 6, wherein
the donor layer defines a thickness ranging from 5 nm to 200 nm, and
the acceptor layer defines a thickness ranging from 5 nm to 200 nm.

21. The transparent photovoltaic device of claim 6, wherein
the first photoactive material has a peak absorption of greater than or equal to 650 nm, and
the second photoactive material has a peak absorption of greater than or equal to 650 nm.

22. The transparent photovoltaic device of claim 21, wherein
the peak absorption of the first photoactive material is greater than or equal to 850 nm.

23. The transparent photovoltaic device of claim 1, wherein the entire device has an average visible transmittance (AVT) of greater than or equal to 30%.

24. The transparent photovoltaic device of claim 1, wherein the device has a power conversion efficiency (PCE) of greater than or equal to 6%.

25. The transparent photovoltaic device of claim 1, wherein the device has a light utilization efficiency (LUE) of greater than or equal to 3.

26. The transparent photovoltaic device of claim 25, wherein the device has a LUE of greater than or equal to 3.5.

27. The transparent photovoltaic device of claim 1, wherein
the device has CIELAB color space coordinates (a*, b*),
a* is less than 0, and
b* is less than 10.

28. The transparent photovoltaic device of claim 1, wherein
a* is less than 0, and
b* is less than 0

29. The transparent photovoltaic device of claim 1, wherein
the device has CIELAB color space coordinates (a*, b*),
a magnitude of a* is less than 15, and
a magnitude of b* is less than 15.

30. The transparent photovoltaic device of claim 1, wherein the device has a color rendering index (CRI) of greater than or equal to 70.

31. The transparent photovoltaic device of claim 1, wherein the device has a maximum external quantum efficiency (EQE) of greater than or equal to 50% at a wavelength of greater than 650 nm.

32. (canceled)

33. The transparent photovoltaic device of claim 1, wherein each of the plurality of planar photoactive layers has a tortuosity of less than 0.2.

34. The transparent photovoltaic device of claim 1, wherein each of the plurality of planar photoactive layers has a porosity of less than 0.2.

35. The transparent photovoltaic device of claim 1, wherein the device has an open circuit voltage within 80% of the excitonic limit.

36. (canceled)

37. A method of preparing a multi-layer transparent photovoltaic (PV) device, the method comprising:
forming a first photoactive layer precursor by depositing a first solution including a first solvent and a first electroactive material onto a substrate;
after the forming the first photoactive layer precursor, forming a second photoactive layer precursor by depositing a second solution including a second solvent and a second electroactive material onto the first photoactive layer precursor; and
forming the multi-layer PV device by drying the first photoactive layer precursor and the second photoactive layer precursor, wherein the multi-layer PV device has a largest absorption peak of less than 430 nm or greater than 650 nm.

38. The method of claim 37, wherein, during the forming the second photoactive layer, less than 25% by volume of the first photoactive material is removed by the second solvent.

39. The method of claim 37, wherein the forming the first photoactive layer and the forming the second active layer each include spin-coating, spray coating, slot-die coating, web coating, curtain coating, vacuum deposition, or any combination thereof.

40. The method of claim 37, wherein the forming the multi-layer PV device includes annealing.

41. (canceled)
